(19) United States
(12) Patent Application Publication
(10) Pub. No.: US 2023/0420615 A1
(43) Pub. Date: Dec. 28, 2023

(54) DISPLAY DEVICE AND MANUFACTURING METHOD OF THE SAME

(71) Applicant: Samsung Display Co., LTD., Yongin-si (KR)

(72) Inventor: Do Yeong PARK, Yongin-si (KR)

(73) Assignee: Samsung Display Co., LTD., Yongin-si (KR)

(21) Appl. No.: 18/112,086

(22) Filed: Feb. 21, 2023

(30) Foreign Application Priority Data
Jun. 23, 2022 (KR) 10-2022-0076524

(51) Int. Cl. H01L 33/38; H01L 33/62; H01L 25/075

(52) U.S. Cl. CPC H01L 33/382; H01L 33/62; H01L 25/0753

(57) ABSTRACT

A display device includes an external bank defining an emission area, a first and second light emitting elements spaced apart from each other in the emission area, each including a first end and a second end, a first connection electrode electrically contacting the first end of the first light emitting element, a second connection electrode spaced apart from the first connection electrode and electrically contacting the first end of the second light emitting element, a first insulating layer on the first and second connection electrodes exposing the second ends of the first and the second light emitting elements, a third connection electrode electrically contacting the second end of the first light emitting element, and a fourth connection electrode electrically contacting the second end of the second light emitting element, and electrically connected to the first connection electrode through a contact hole penetrating the first insulating layer.

### CROSS-REFERENCE TO RELATED APPLICATION(S)

This application claims priority to and benefits of Korean Patent Application No. 10-2022-0076524 under 35 U.S.C. 119, filed on Jun. 23, 2022, in the Korean Intellectual Property Office (KIPO), the entire contents of which are incorporated herein by reference.

### BACKGROUND

### 1. Technical Field

The disclosure relates to a display device and a manufacturing method of the same.

### 2. Description of the Related Art

The importance of display devices has steadily increased with the development of multimedia technology. In response thereto, various types of display devices such as an organic light emitting display (OLED), a liquid crystal display (LCD) and the like have been used.

A display device is a device for displaying an image, and includes a display panel, such as an organic light emitting display panel or a liquid crystal display panel. The light emitting display panel may include light emitting elements, e.g., light emitting diodes (LED), and examples of the light emitting diode include an organic light emitting diode (OLED) using an organic material as a fluorescent material and an inorganic light emitting diode using an inorganic material as a fluorescent material.

An inorganic light emitting diode using an inorganic semiconductor as a fluorescent material has an advantage in that it has durability even in a high temperature environment, and has higher efficiency of blue light than an organic light emitting diode.

### SUMMARY

Aspects of the disclosure provide a display device with improved lighting efficiency of pixels.

However, aspects of the disclosure are not restricted to the one set forth herein. The above and other aspects of the disclosure will become more apparent to one of ordinary skill in the art to which the disclosure pertains by referencing the detailed description of the disclosure given below.

According to an embodiment a display device may include an external bank disposed on a substrate defining an emission area, a first light emitting element and a second light emitting element spaced apart from each other, each disposed on the substrate in the emission area and including a first end having a first polarity and a second end having a second polarity, a first connection electrode disposed on the substrate and electrically contacting the first end of the first light emitting element, a second connection electrode disposed on the substrate, spaced apart from the first connection electrode, and electrically contacting the first end of the second light emitting element, a first insulating layer disposed on the first connection electrode and the second connection electrode and exposing the second end of the first light emitting element and the second end of the second light emitting element, a third connection electrode disposed on the first insulating layer and electrically contacting the second end of the first light emitting element, and a fourth connection electrode disposed on the first insulating layer, spaced apart from the third connection electrode, electrically contacting the second end of the second light emitting element, and electrically connected to the first connection electrode through a first contact hole penetrating the first insulating layer.

In an embodiment, each of the first end of the first light emitting element and the first end of the second light emitting element may include a p-type semiconductor, each of the second end of the first light emitting element and the second end of the second light emitting element may include an n-type semiconductor, and the second end of the first light emitting element and the second end of the second light emitting element may be disposed to face each other.

In an embodiment, the first contact hole may be not disposed in the emission area.

In an embodiment, in the emission area, the first connection electrode and the fourth connection electrode may be spaced apart from each other, the third connection electrode may be disposed between the first connection electrode and the fourth connection electrode, the second connection electrode and the third connection electrode may be spaced apart from each other, and the fourth connection electrode may be disposed between the second connection electrode and the third connection electrode.

In an embodiment, a first power voltage may be supplied to the second connection electrode, a second power voltage may be supplied to the third connection electrode, and a potential value of the first power voltage may be greater than a potential value of the second power voltage.

In an embodiment, the display device may further include a third light emitting element and a fourth light emitting element spaced apart from the first light emitting element and the second light emitting element, each disposed on the substrate in the emission area and including a first end having the first polarity and a second end having the second polarity, a fifth connection electrode disposed between the substrate and the first insulating layer and electrically contacting the first end of the third light emitting element, a sixth connection electrode disposed between the substrate and the first insulating layer, spaced apart from the fifth connection electrode, and electrically contacting the first end of the fourth light emitting element, a seventh connection electrode disposed on the first insulating layer and electrically contacting the second end of the third light emitting element, and an eighth connection electrode disposed on the first insulating layer, spaced apart from the seventh connection electrode, and electrically contacting the second end of the fourth light emitting element. The first connection electrode and the seventh connection electrode may be electrically connected through a second contact hole penetrating the first insulating layer, and the fourth connection electrode and the sixth connection electrode may be electrically connected through a third contact hole penetrating the first insulating layer.

In an embodiment, each of the first end of the third light emitting element and the first end of the fourth light emitting element may include a p-type semiconductor, each of the second end of the third light emitting element and the second end of the fourth light emitting element may include an n-type semiconductor, the second end of the third light emitting element and the second end of the fourth light emitting element may be disposed to face each other, the second contact hole may be disposed between the first light emitting element and the third light emitting element in the emission area, and the third contact hole may be disposed between the second light emitting element and the fourth light emitting element in the emission area.

In an embodiment, the first insulating layer may be not disposed between the third connection electrode and the fourth connection electrode.

In an embodiment, each of the first end of the first light emitting element and the first end of the second light emitting element may include a p-type semiconductor, each of the second end of the first light emitting element and the second end of the second light emitting element may include an n-type semiconductor, and the first end of the first light emitting element and the first end of the second light emitting element may be disposed to face each other.

In an embodiment, the first contact hole may be not disposed in the emission area.

In an embodiment, in the emission area, the first connection electrode and the fourth connection electrode may be spaced apart from each other, the second connection electrode may be disposed between the first connection electrode and the fourth connection electrode, the second connection electrode and the third connection electrode may be spaced apart from each other, and the first connection electrode may be disposed between the second connection electrode and the third connection electrode.

In an embodiment, a first power voltage may be supplied to the second connection electrode, a second power voltage may be supplied to the third connection electrode, and a potential value of the first power voltage may be greater than a potential value of the second power voltage.

In an embodiment, the display device may further include a third light emitting element and a fourth light emitting element spaced apart from the first light emitting element and the second light emitting element each disposed on the substrate in the emission area and including a first end having the first polarity and a second end having the second polarity, a fifth connection electrode disposed between the substrate and the first insulating layer and electrically contacting the first end of the third light emitting element, a sixth connection electrode disposed between the substrate and the first insulating layer, spaced apart from the fifth connection electrode, and electrically contacting the first end of the fourth light emitting element, a seventh connection electrode disposed on the first insulating layer and electrically contacting the second end of the third light emitting element, and an eighth connection electrode disposed on the first insulating layer, spaced apart from the seventh connection electrode, and electrically contacting the second end of the fourth light emitting element. The third connection electrode and the fifth connection electrode may be electrically connected through a second contact hole penetrating the first insulating layer, and the second connection electrode and the eighth connection electrode may be electrically connected through a third contact hole penetrating the first insulating layer.

In an embodiment, each of the first end of the third light emitting element and the first end of the fourth light emitting element may include a p-type semiconductor, each of the second end of the third light emitting element and the second end of the fourth light emitting element may include an n-type semiconductor, the first end of the third light emitting element and the first end of the fourth light emitting element may be disposed to face each other, the second contact hole may be disposed between the first light emitting element and the third light emitting element in the emission area, and the third contact hole may be disposed between the second light emitting element and the fourth light emitting element in the emission area.

In an embodiment, the first insulating layer may be not disposed between the third connection electrode and the external bank and between the fourth connection electrode and the external bank.

According to an embodiment of the disclosure, a display device may include an external bank disposed on a substrate defining an emission area, a first light emitting element and a second light emitting element spaced apart from each other, each disposed on the substrate in the emission area and including a first end having a first polarity and a second end having a second polarity, a first connection electrode disposed on the substrate and electrically contacting the first end of the first light emitting element, a second connection electrode disposed on the substrate, spaced apart from the first connection electrode, and electrically contacting the first end of the second light emitting element, a first insulating layer disposed on the first connection electrode and the second connection electrode and exposing the second end of the first light emitting element and the second end of the second light emitting element, a third connection electrode disposed on the first insulating layer, electrically contacting the second end of the first light emitting element, and having a width greater than a width of the first connection electrode in a direction, and a fourth connection electrode disposed on the first insulating layer, spaced apart from the third connection electrode, electrically contacting the second end of the second light emitting element, and having a width greater than a width of the second connection electrode in the direction.

In an embodiment, each of the first end of the first light emitting element and the first end of the second light emitting element may include a p-type semiconductor, each of the second end of the first light emitting element and the second end of the second light emitting element may include an n-type semiconductor, and the second end of the first light emitting element and the second end of the second light emitting element may be disposed to face each other.

In an embodiment, the display device may further include a first alignment electrode, a second alignment electrode, and a third alignment electrode sequentially arranged to be spaced apart from each other on the substrate in the emission area. The first light emitting element may be disposed between the first alignment electrode and the second alignment electrode, the second light emitting element may be disposed between the second alignment electrode and the third alignment electrode, the third connection electrode may be disposed on the second alignment electrode and cover at least half of a distance between the first alignment electrode and the second alignment electrode, and the fourth connection electrode may be disposed on the second alignment electrode and cover at least half of a distance between the second alignment electrode and the third alignment electrode.

In an embodiment, each of the first end of the first light emitting element and the first end of the second light emitting element may include a p-type semiconductor, each of the second end of the first light emitting element and the second end of the second light emitting element may include an n-type semiconductor, and the first end of the first light emitting element and the first end of the second light emitting element may be disposed to face each other.

In an embodiment, the display device may further include a first alignment electrode, a second alignment electrode, and a third alignment electrode sequentially arranged to be spaced apart from each other on the substrate in the emission area. The second light emitting element may be disposed between the first alignment electrode and the second alignment electrode, the first light emitting element may be disposed between the second alignment electrode and the third alignment electrode, the third connection electrode may be disposed on the third alignment electrode and cover at least half of a distance between the second alignment electrode and the third alignment electrode, and the fourth connection electrode may be disposed on the first alignment electrode and cover at least half of a distance between the first alignment electrode and the second alignment electrode.

In the display device according to one embodiment, lighting efficiency of pixels may be improved.

However, the effects of the disclosure are not limited to the aforementioned effects, and various other effects are included in the disclosure.

### BRIEF DESCRIPTION OF THE DRAWINGS

The above and other aspects and features of the disclosure will become more apparent by describing in detail embodiments thereof with reference to the attached drawings, in which:

FIG. 1 is a plan view of a display device according to one embodiment;

FIG. 2 is a plan view illustrating a layout of wires of a display device according to one embodiment;

FIG. 3 is a schematic diagram of an equivalent circuit of a pixel of a display device according to one embodiment;

FIG. 4 is a plan view illustrating a structure of a pixel of a display device according to one embodiment;

FIG. 5 is a perspective view illustrating the structure of the light emitting element of FIG. 4;

FIG. 6 is an enlarged view of area A of FIG. 4;

FIG. 7 is a plan view illustrating a second insulating layer disposed in an emission area;

FIG. 8 is a plan view illustrating a third insulating layer disposed in an emission area;

FIG. 9 is a schematic cross-sectional view of a pixel taken along line X1-X1′ of FIG. 6;

FIG. 10 is a schematic cross-sectional view of a pixel taken along line X2-X2′ of FIGS. 6 to 8;

FIG. 11 is a schematic cross-sectional view of a pixel taken along line X3-X3′ of FIGS. 6 to 8;

FIG. 12 is a schematic cross-sectional view of a pixel taken along line X4-X4′ of FIGS. 6 to 8;

FIGS. 13 to 18 are schematic cross-sectional views showing the steps of a process of manufacturing a display device according to one embodiment;

FIGS. 19 to 21 are schematic cross-sectional views showing the steps of another example of a process of manufacturing a display device according to one embodiment;

FIG. 22 is a plan view illustrating a pixel structure of a display device according to another embodiment;

FIG. 23 is a schematic cross-sectional view of a pixel taken along line X5-X5′ of FIG. 22;

FIG. 24 is a plan view illustrating a pixel structure of a display device according to yet another embodiment; and

FIG. 25 is a plan view illustrating a pixel structure of a display device according to yet another embodiment.

### DETAILED DESCRIPTION OF THE EMBODIMENTS

The embodiments will now be described more fully hereinafter with reference to the accompanying drawings, in which embodiments of the disclosure are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

When an element, such as a layer, is referred to as being “on”, “connected to”, or “coupled to” another element or layer, it may be directly on, connected to, or coupled to the other element or layer or intervening elements or layers may be present. When, however, an element or layer is referred to as being “directly on”, “directly connected to”, or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the disclosure. Similarly, the second element could also be termed the first element.

In the specification and the claims, the phrase “at least one of” is intended to include the meaning of “at least one selected from the group of” for the purpose of its meaning and interpretation. For example, “at least one of A and B” may be understood to mean “A, B, or A and B.”

Features of each of various embodiments of the disclosure may be partially or entirely combined with each other and may technically variously interwork with each other, and respective embodiments may be implemented independently of each other or may be implemented together in association with each other.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

Hereinafter, embodiments will be described in detail with reference to the accompanying drawings.

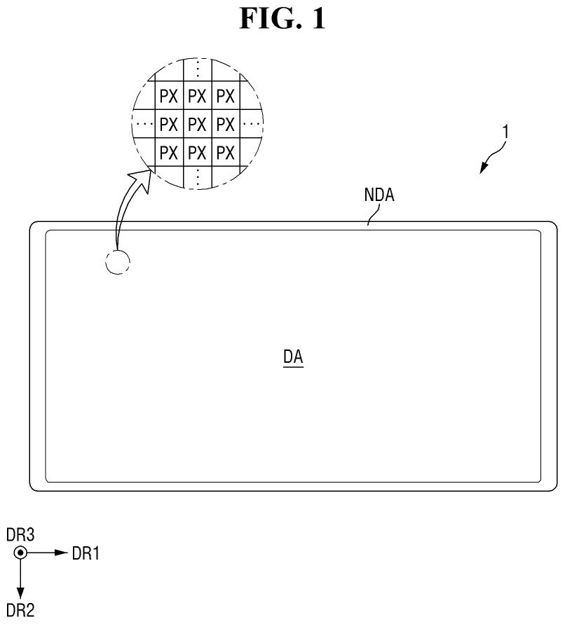

FIG. 1 is a plan view of a display device according to one embodiment.

A first direction DR1, a second direction DR2, and a third direction DR3 are defined as shown in FIG. 1. The first direction DR1 and the second direction DR2 may be perpendicular to each other, the first direction DR1 and the third direction DR3 may be perpendicular to each other, and the second direction DR2 and the third direction DR3 may be perpendicular to each other. It may be understood that the first direction DR1 refers to a horizontal direction in the drawing, the second direction DR2 refers to a vertical direction in the drawing, and the third direction DR3 refers to an upward and downward direction (i.e., a thickness direction) in the drawing.

In the following specification, unless otherwise stated, “direction” may refer to both of directions extending along the direction. Further, when it is necessary to distinguish both “directions” extending in both sides, one side will be referred to as “one side in the direction” and the other side will be referred to as “the other side in the direction.” Referring to FIG. 1, a direction in which an arrow is directed is referred to as one side, and the opposite direction is referred to as the other side.

Hereinafter, for simplicity of description, when referring to a display device 1 or the surfaces of each member constituting the display device 1, a surface facing the direction in which the image is displayed, for example, the third direction DR3 may be referred to as a top surface, and the opposite surface is referred to as a bottom surface. However, the disclosure is not limited thereto, and a surface and another surface of the member may be referred to as a front surface and a rear surface, respectively, or may also be referred to as a first surface or a second surface. In addition, in describing the relative position of each of the members of the display device 1, a side of the third direction DR3 may be referred to as an upper side and another side of the third direction DR3 may be referred to as a lower side.

Referring to FIG. 1, a display device 1 may display a moving image or a still image. The display device 1 may be any electronic device providing a display screen. Examples of the display device 1 may include a television, a laptop computer, a monitor, a billboard, an Internet-of-Things device, a mobile phone, a smartphone, a tablet personal computer (PC), an electronic watch, a smart watch, a watch phone, a head-mounted display, a mobile communication terminal, an electronic notebook, an electronic book, a portable multimedia player (PMP), a navigation device, a game machine, a digital camera, a camcorder and the like, which provide a display screen.

The display device 1 may include a display panel which provides a display screen. Examples of the display panel may include an inorganic light emitting diode display panel, an organic light emitting display panel, a quantum dot light emitting display panel, a plasma display panel and a field emission display panel. In the following description, a case where an inorganic light emitting diode display panel is applied as a display panel will be described, but the disclosure is not limited thereto, and other display panels may be applied within the same scope of technical spirit.

The shape of the display device 1 may be variously modified. For example, the display device 1 may have a shape such as a rectangular shape elongated in a horizontal direction, a rectangular shape elongated in a vertical direction, a square shape, a quadrilateral shape with rounded corners (vertices), other polygonal shapes, and a circular shape. The shape of a display area DA of the display device 1 may also be similar to the overall shape of the display device 1. FIG. 1 illustrates the display device 1 having a rectangular shape elongated in a second direction DR2.

The display device 1 may include the display area DA and a non-display area NDA. The display area DA may be an area where a screen can be displayed, and the non-display area NDA may be an area where a screen is not displayed. The display area DA may also be referred to as an active region, and the non-display area NDA may also be referred to as a non-active region. The display area DA may substantially occupy the center of the display device 1.

The display area DA may include multiple pixels PX. The pixels PX may be arranged in matrix. The shape of each pixel PX may be a rectangular or square shape in a plan view. However, the disclosure is not limited thereto, and it may be a rhombic shape in which each side is inclined with respect to one direction. The pixels PX may be arranged in a stripe type or an island type. Each of the pixels PX may include one or more light emitting elements that emit light of a specific wavelength band to display a specific color.

The non-display area NDA may be disposed adjacent to the display area DA. The non-display area NDA may completely or partially surround the display area DA. The display area DA may have a rectangular shape, and the non-display area NDA may be disposed adjacent to four sides of the display area DA. The non-display area NDA may form a bezel of the display device 1. Wires or circuit drivers included in the display device 1 may be disposed in the non-display area NDA, or external devices may be mounted thereon.

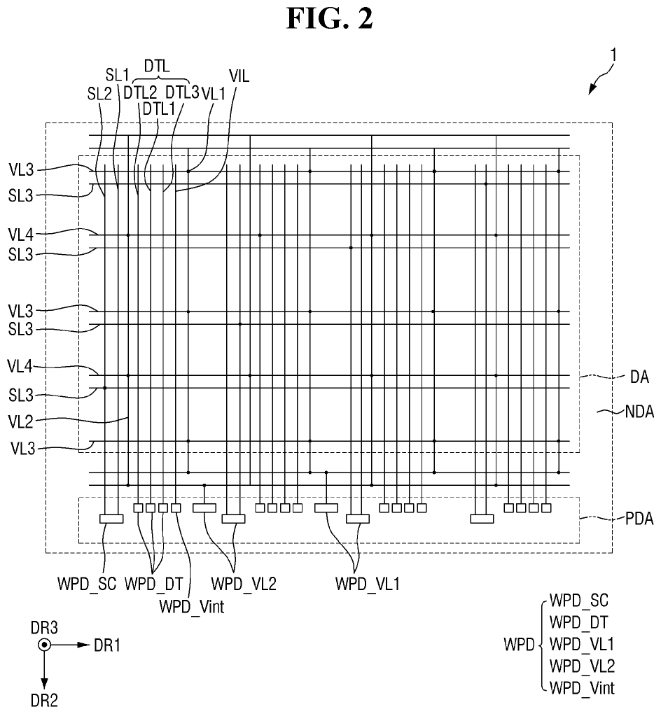

FIG. 2 is a plan view illustrating a layout of wires of a display device according to one embodiment.

Referring to FIG. 2, the display device 1 may include multiple wires. The display device 1 may include multiple scan lines SL (SL1, SL2, and SL3), multiple data lines DTL (DTL1, DTL2, and DTL3), an initialization voltage line VIL, and multiple voltage lines VL (VL1, VL2, VL3, and VL4). Although not shown in the drawing, other wires may be further provided in the display device 1. The wires may include wires formed in a first conductive layer and extending in a first direction DR1, and wires formed in a third conductive layer and extending in the second direction DR2. However, the extension directions of the wires are not limited thereto.

The first scan line SL1 and the second scan line SL2 may be disposed to extend in the second direction DR2. The first scan line SL1 and the second scan line SL2 may be disposed adjacent to each other, and may be disposed to be spaced apart from other scan lines in the first direction DR1. The first scan line SL1 and the second scan line SL2 may be connected to a scan line pad WPD_SC connected to a scan driver (not illustrated). The first scan line SL1 and the second scan line SL2 may be disposed to extend from the pad area PDA disposed in the non-display area NDA to the display area DA.

The third scan line SL3 may be disposed to extend in the first direction DR1, and may be disposed to be spaced apart from adjacent third scan line SL3 in the second direction DR2. One third scan line SL3 may be connected to one or more first scan lines SL1 or one or more second scan lines SL2. The scan lines SL may have a mesh structure in the entire surface of the display area DA, but the disclosure is not limited thereto.

The term “connected” as used herein may mean not only that one member is connected to another member by a physical contact, but also that one member is connected to another member through yet another member. This may also be understood as a part and another part as integral elements are connected into an integrated element via another element. Furthermore, if one element is connected to another element, this may be construed as including an electrical connection via another element in addition to a direct connection by physical contact.

The data lines DTL may be disposed to extend in the second direction DR2. The data line DTL may include a first data line DTL1, a second data line DTL2, and a third data line DTL3, and each one of the first to third data lines DTL1, DTL2, and DTL3 may form a pair and may be disposed adjacent to each other. Each of the data lines DTL1, DTL2, and DTL3 may be disposed to extend from the pad area PDA disposed in the non-display area NDA to the display area DA. However, the disclosure is not limited thereto, and the data lines DTL may be spaced apart from each other at equal intervals between a first voltage line VL1 and a second voltage line VL2 to be described later.

The initialization voltage line VIL may be disposed to extend in the second direction DR2. The initialization voltage line VIL may be disposed between the data lines DTL and the first voltage line VL1. The initialization voltage line VIL may be disposed to extend from the pad area PDA disposed in the non-display area NDA to the display area DA.

The first voltage line VL1 and the second voltage line VL2 may be disposed to extend in the second direction DR2, and the third voltage line VL3 and the fourth voltage line VL4 may be disposed to extend in the first direction DR1. The first voltage line VL1 and the second voltage line VL2 may be alternately arranged in the first direction DR1, and the third voltage line VL3 and the fourth voltage line VL4 may be alternately arranged in the second direction DR2. The first voltage line VL1 and the second voltage line VL2 may be disposed to extend in the second direction DR2 to cross the display area DA. Portions of the third voltage line VL3 and the fourth voltage line VL4 may be disposed in the display area DA and other portions may be disposed in the non-display area NDA positioned on both sides of the display area DA in the second direction DR2, respectively. The first voltage line VL1 and the second voltage line VL2 may be formed of the first conductive layer, and the third voltage line VL3 and the fourth voltage line VL4 may be formed of the third conductive layer disposed on a layer different from the first conductive layer. The first voltage line VL1 may be connected to at least one third voltage line VL3, the second voltage line VL2 may be connected to at least one fourth voltage line VL4, and the voltage lines VL may have a mesh structure in the entire display area DA. However, the disclosure is not limited thereto.

The first scan line SL1, the second scan line SL2, the data line DTL, the initialization voltage line VIL, the first voltage line VL1, and the second voltage line VL2 may be electrically connected to at least one line pad WPD. Each line pad WPD may be disposed in the non-display area NDA. In one embodiment, each of the line pads WPD may be disposed in the pad area PDA positioned on the lower side, which is another side of the display area DA in the second direction DR2. The first scan line SL1 and the second scan line SL2 may be connected to the scan line pad WPD_SC disposed in the pad area PDA, and the data lines DTL may be connected to the data line pads WPD DT different from each other, respectively. The initialization voltage line VIL may be connected to an initialization line pad WPD_Vint, the first voltage line VL1 may be connected to a first voltage line pad WPD_VL1, and the second voltage line VL2 may be connected to a second voltage line pad WPD_VL2. The external devices may be mounted on the line pads WPD. The external devices may be mounted on the line pads WPD by applying an anisotropic conductive film, ultrasonic bonding or the like. The drawing illustrates that each of the line pads WPD is disposed on the pad area PDA disposed on the lower side of the display area DA, but is not limited thereto. Some of the line pads WPD may be disposed on the upper side, the left, or the right side of the display area DA.

Each pixel PX or sub-pixel SPXn (n is an integer greater than 1) of the display device 1 may include a pixel driving circuit. The above-described wires may pass through each pixel PX or the vicinity thereof to apply a driving signal to each pixel driving circuit. The pixel driving circuit may include transistors and capacitors. The number of the transistors and the capacitors of each pixel driving circuit may be variously modified. According to one embodiment, in each sub-pixel SPXn of the display device 1, the pixel driving circuit may have a 3T1C structure including three transistors and one capacitor. Hereinafter, the pixel driving circuit of the 3T1C structure will be described as an example, but the disclosure is not limited thereto, and various other modified structures such as a 2T1C structure, a 7T1C structure, and a 6T1C structure may be applied.

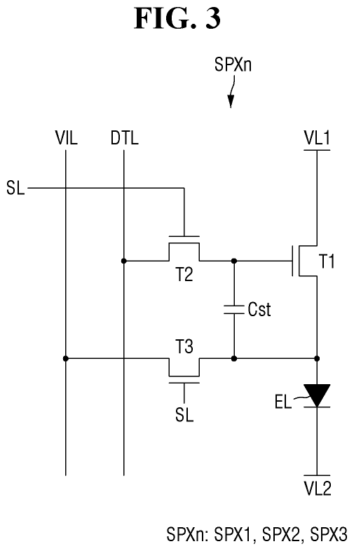

FIG. 3 is a schematic diagram of an equivalent circuit of a pixel of a display device according to one embodiment.

Referring to FIG. 3, each sub-pixel SPXn of the display device 1 according to one embodiment may include three transistors T1, T2 and T3 and one storage capacitor Cst in addition to a light emitting diode EL.

The light emitting diode EL may emit light by a current supplied through a first transistor T1. The light emitting diode EL may include a first electrode, a second electrode, and at least one light emitting element disposed between them. The light emitting element may emit light of a specific wavelength band by electrical signals transmitted from the first electrode and the second electrode.

An end of the light emitting diode EL may be connected to the source electrode of the first transistor T1, and another end thereof may be connected to the second voltage line VL2 to which a low potential voltage (hereinafter, a second power voltage) lower than a high potential voltage (hereinafter, a first power voltage) of the first voltage line VL1 is supplied.

The first transistor T1 may adjust a current flowing from the first voltage line VL1, to which the first power voltage is supplied, to the light emitting diode EL according to the voltage difference between the gate electrode and the source electrode. For example, the first transistor T1 may be a driving transistor for driving the light emitting diode EL. The gate electrode of the first transistor T1 may be connected to the source electrode of the second transistor T2, the source electrode of the first transistor T1 may be connected to the first electrode of the light emitting diode EL, and the drain electrode of the first transistor T1 may be connected to the first voltage line VL1 to which the first power voltage is applied.

The second transistor T2 may be turned on by a scan signal of the scan line SL to connect the data line DTL to the gate electrode of the first transistor T1. The gate electrode of the second transistor T2 may be connected to the scan line SL, the source electrode thereof may be connected to the gate electrode of the first transistor T1, and the drain electrode thereof may be connected to the data line DTL.

The third transistor T3 may be turned on by a scan signal of the scan line SL to connect the initialization voltage line VIL to the first electrode of the light emitting diode EL. The gate electrode of the third transistor T3 may be connected to the scan line SL, the drain electrode thereof may be connected to the initialization voltage line VIL, and the source electrode thereof may be connected to the first electrode of the light emitting diode EL or to the source electrode of the first transistor T1.

However, the source electrode and the drain electrode of each of the transistors T1, T2, and T3 are not limited to those described above. Each of the transistors T1, T2, and T3 may be formed of a thin film transistor. In FIG. 3, each of the transistors T1, T2, and T3 are described as an N-type metal oxide semiconductor field effect transistor (MOSFET), but the disclosure is not limited thereto. For example, each of the transistors T1, T2, and T3 may be formed of a P-type MOSFET. In another embodiment, some of the transistors T1, T2, and T3 may be formed of an N-type MOSFET, and the others may be formed of a P-type MOSFET.

The storage capacitor Cst may be formed between the gate electrode and the source electrode of the first transistor T1. The storage capacitor Cst may store a voltage in difference between a gate electrode and a source electrode of the first transistor T1.

In the embodiment of FIG. 3, the gate electrode of the second transistor T2 may be connected to the scan line SL, and the gate electrode of the third transistor T3 may be connected to the scan line SL. In other words, the second transistor T2 and the third transistor T3 may be turned on by a scan signal applied from the same scan line. However, the disclosure is not limited thereto, and the second transistor T2 and the third transistor T3 may be connected to different scan lines to be turned on in response to scan signals applied from different scan lines.

Hereinafter, a structure of the pixel PX of the display device 1 according to one embodiment will be described.

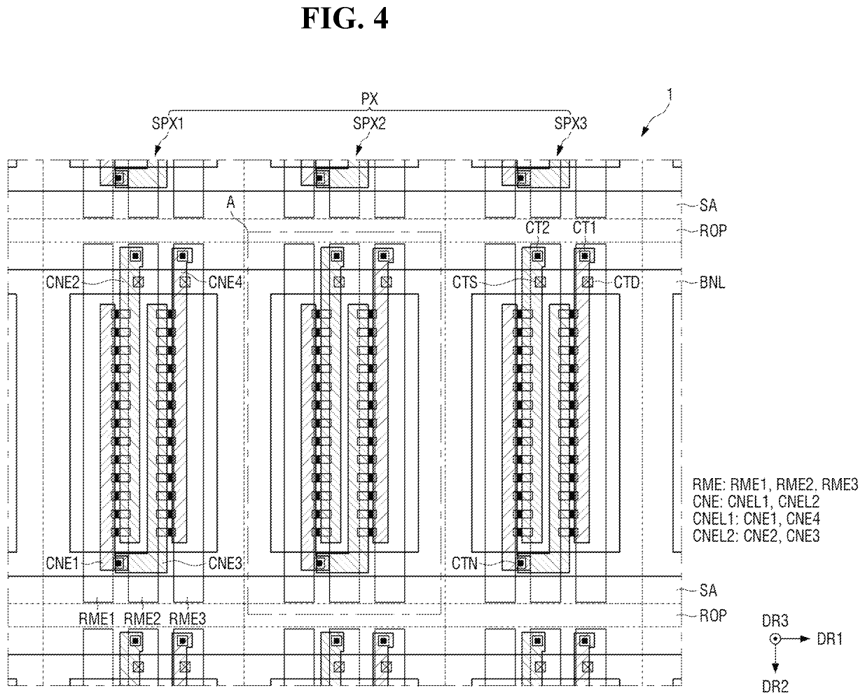

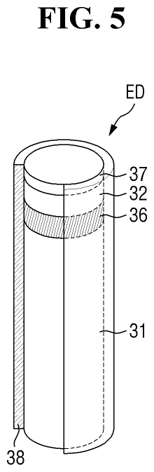

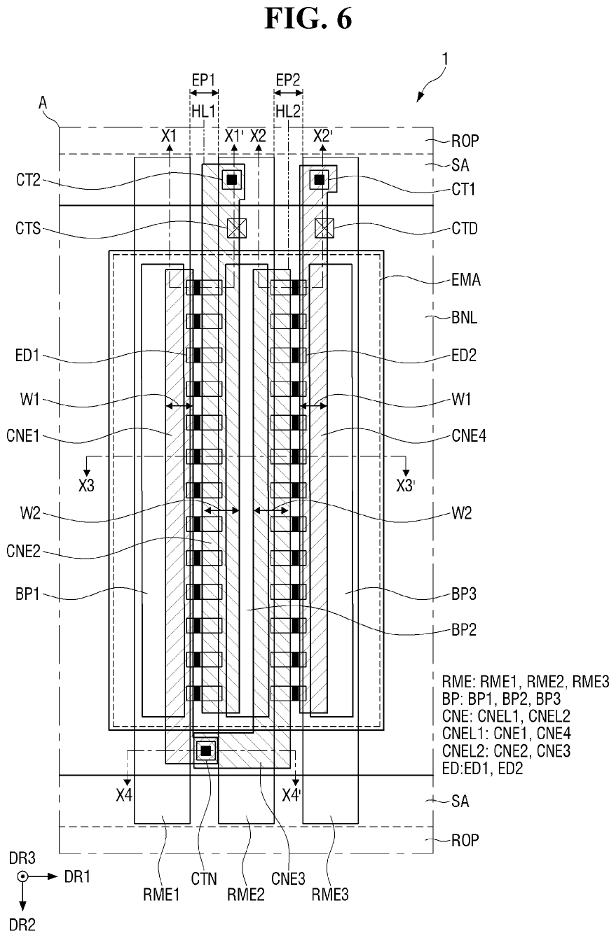

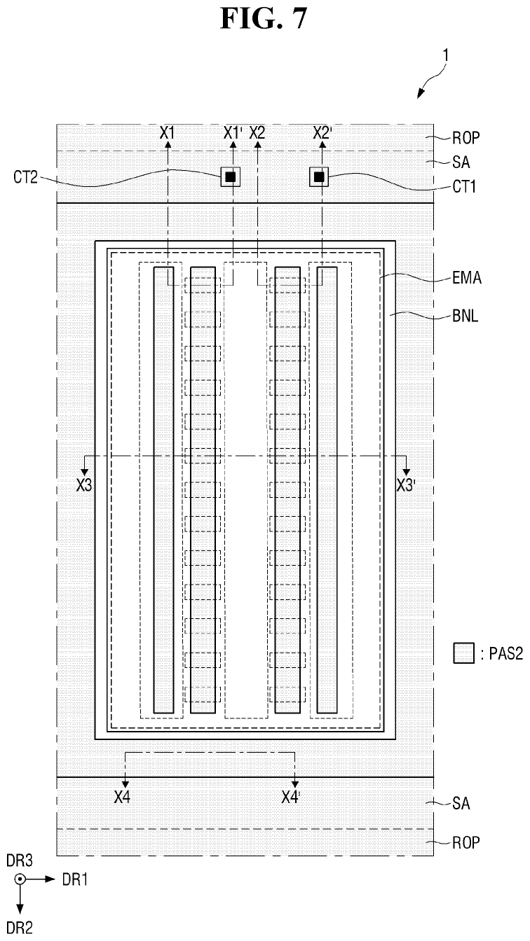

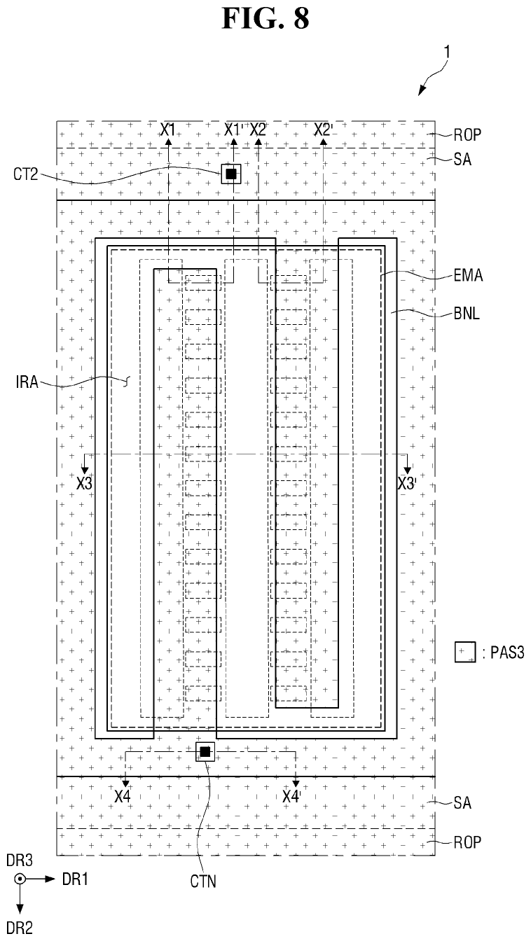

FIG. 4 is a plan view illustrating a structure of a pixel of a display device according to one embodiment. FIG. 5 is a perspective view illustrating the structure of the light emitting element of FIG. 4. FIG. 6 is an enlarged view of area A of FIG. 4. FIG. 7 is a plan view illustrating a second insulating layer disposed in an emission area. FIG. 8 is a plan view illustrating a third insulating layer disposed in an emission area.

FIGS. 4 and 6 illustrate a planar disposition of alignment electrodes RME, an external bank BNL, multiple light emitting elements ED, and a connection electrode CNE disposed in one pixel PX of the display device 1.

Referring to FIGS. 4 and 6, each of the pixels PX of the display device 1 may include multiple sub-pixels SPXn. For example, one pixel PX may include a first sub-pixel SPX1, a second sub-pixel SPX2, and a third sub-pixel SPX3. The first sub-pixel SPX1 may emit light of a first color, the second sub-pixel SPX2 may emit light of a second color, and the third sub-pixel SPX3 may emit light of a third color. For example, the first color may be blue, the second color may be green, and the third color may be red. However, the disclosure is not limited thereto, and the sub-pixels SPXn may emit light of the same color. In one embodiment, each of the sub-pixels SPXn may emit blue light. Although it is illustrated in the drawing that one pixel PX includes three sub-pixels SPXn, the disclosure is not limited thereto, and the pixel PX may include a larger number of sub-pixels SPXn. Hereinafter, for simplicity of description, a case where one pixel PX includes three sub-pixels SPXn will be described.

The first sub-pixel SPX1, the second sub-pixel SPX2, and the third sub-pixel SPX3 may be sequentially arranged in the first direction DR1. For example, the first sub-pixel SPX1 may be disposed on a side of the second sub-pixel SPX2 in the first direction DR1.

Accordingly, at least one sub-pixel SPXn of the one pixel PX may be adjacent to at least one sub-pixel SPXn of the pixel PX adjacent to the one pixel PX. For example, with reference to FIG. 4, the third sub-pixel SPX3 of the pixel PX may be adjacent to the first sub-pixel SPX1 of the adjacent pixel PX in first direction DR1.

Each sub-pixel SPXn of the display device 1 may include an emission area EMA and a non-emission area. The emission area EMA may be an area in which the light emitting element ED is disposed to emit light of a specific wavelength band. The non-emission area may be a region in which the light emitting element ED is not disposed and a region from which light is not emitted because light emitted from the light emitting element ED does not reach there.

The emission area EMA may be defined by the external bank BNL. In other words, the emission area EMA may be a space surrounded by the external bank BNL. In some embodiments, the emission area EMA may have a rectangular shape including a short side in the first direction DR1 and a long side in the second direction DR2, but is not limited thereto.

The emission area EMA may include a region in which the light emitting element ED is disposed, and a region adjacent to the light emitting element ED in which the lights emitted from the light emitting element ED are emitted. For example, the emission area EMA may include a region in which the light emitted from the light emitting element ED is reflected or refracted by another member and emitted. The light emitting elements ED may be disposed in each sub-pixel SPXn, and the emission area may be formed to include an area where the light emitting elements ED are disposed and an area adjacent thereto.

Although it is shown in the drawing that the sub-pixels SPXn have the emission areas EMA that are substantially identical in size, the disclosure is not limited thereto. In some embodiments, the emission areas EMA of the sub-pixels SPXn may have different sizes according to a color or wavelength band of light emitted from the light emitting element ED disposed in each sub-pixel SPXn.

Each sub-pixel SPXn may further include a sub-region SA disposed in the non-emission area. The sub-region SA may be a divided area according to the disposition of the alignment electrodes RME. The sub-region SA may be disposed on a side and another side of the emission area EMA in the second direction DR2. The emission areas EMA may be alternately arranged in the second direction DR2, and the sub-region SA may extend in the first direction DR1. Each of multiple emission areas EMA and the sub-regions SA may be repeatedly disposed in the second direction DR2. Each of the emission areas EMA may be disposed between the sub-regions SA.

The sub-region SA may be a region shared by the sub-pixels SPXn adjacent to each other in the first direction DR1. For example, the first sub-pixel SPX1, the second sub-pixel SPX2, and the third sub-pixel SPX3 may share a sub-region SA. The sub-region SA may be a region shared by the sub-pixels SPXn adjacent to each other in the second direction DR2. For example, the sub-regions SA disposed on both sides of the external bank BNL in the second direction DR2 illustrated in FIG. 4 may be shared by the sub-pixel SPXn illustrated in the drawing and the sub-pixels SPXn not illustrated in the drawing and adjacent to each other in the second direction DR2.

Light may not be emitted from the sub-region SA because the light emitting element ED is not disposed in the sub-region SA, and an alignment electrode RME disposed in each sub-pixel SPXn may be partially disposed in the sub-region SA. The alignment electrodes RME disposed in different sub-pixels SPXn may be disposed to be separated at a separation portion ROP of the sub-region SA.

Multiple alignment electrodes RME and the connection electrodes CNE may be disposed in each sub-pixel SPXn in a shape extending in the second direction DR2.

The alignment electrode RME may include a first alignment electrode RME1, a second alignment electrode RME2, and a third alignment electrode RME3 sequentially arranged in the first direction DR1 per one sub-pixel SPXn. The first alignment electrode RME1, the second alignment electrode RME2, and the third alignment electrode RME3 may be disposed to be spaced apart from each other in the first direction DR1.

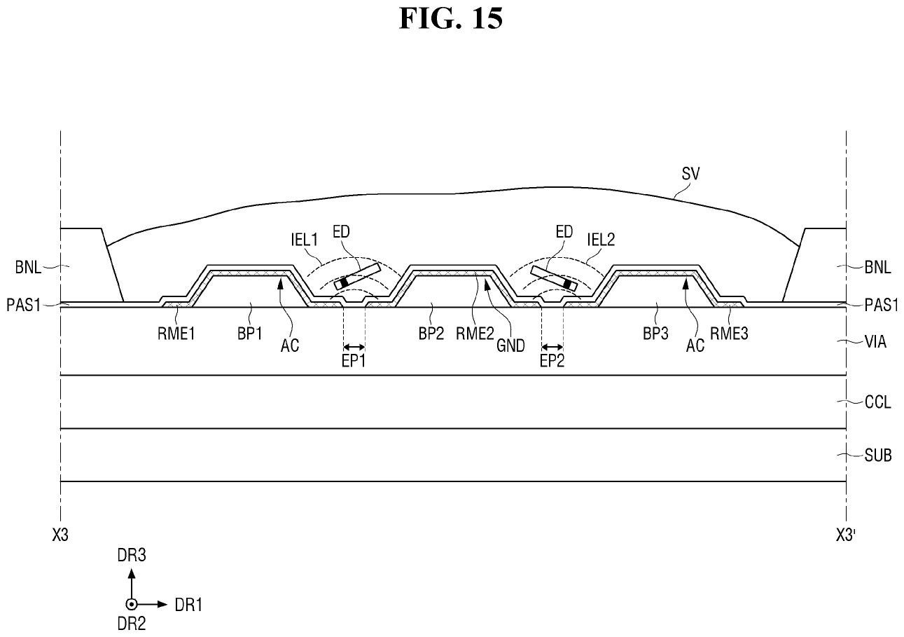

The first alignment electrode RME1, the second alignment electrode RME2, and the third alignment electrode RME3 may be applied with different alignment signals AC and GND (see FIG. 15) in the manufacturing process of the display device 1 according to one embodiment to be described later. A detailed description thereof will be given later.

The first alignment electrode RME1 may be disposed on the other side of the emission area EMA in the first direction DR1. For example, the first alignment electrode RME1 may be disposed to be spaced apart in the first direction DR1 from a portion of the external bank BNL forming the other side of the emission area EMA in the first direction DR1.

The first alignment electrode RME1 may have a shape extending in the second direction DR2. In some embodiments, the first alignment electrode RME1 may have a rectangular planar shape in a plan view, but is not limited thereto. FIGS. 4 and 6 illustrate that the first alignment electrode RME1 has a rectangular planar shape.

The third alignment electrode RME3 may be disposed on one side of the emission area EMA in the first direction DR1. For example, the third alignment electrode RME3 may be disposed to be spaced apart in the first direction DR1 from a portion of the external bank BNL forming one side of the emission area EMA in the first direction DR1.

The third alignment electrode RME3 may have a shape extending in the second direction DR2. In some embodiments, the third alignment electrode RME3 may have a rectangular planar shape in a plan view, but is not limited thereto. FIGS. 4 and 6 illustrate that the third alignment electrode RME3 has a rectangular planar shape.

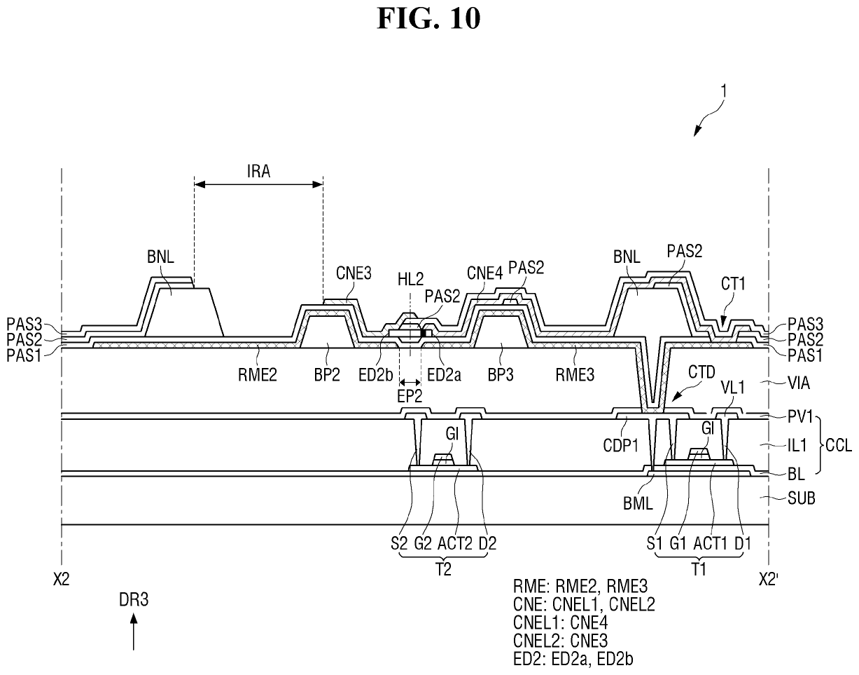

The third alignment electrode RME3 may be electrically connected to a circuit element layer CCL (see FIG. 10) to be described later through a first electrode contact hole CTD. The third alignment electrode RME3 may be applied with the above-described first power voltage through the first electrode contact hole CTD.

The second alignment electrode RME2 may be disposed on one side of the first alignment electrode RME1 in the first direction DR1. The second alignment electrode RME2 may be disposed between the first alignment electrode RME1 and the third alignment electrode RME3. For example, the second alignment electrode RME2 may be disposed at the center of the emission area EMA, but is not limited thereto.

The second alignment electrode RME2 may have a shape extending in the second direction DR2. In some embodiments, the second alignment electrode RME2 may have a rectangular planar shape in a plan view, but is not limited thereto. FIGS. 4 and 6 illustrate that the second alignment electrode RME2 has a rectangular planar shape.

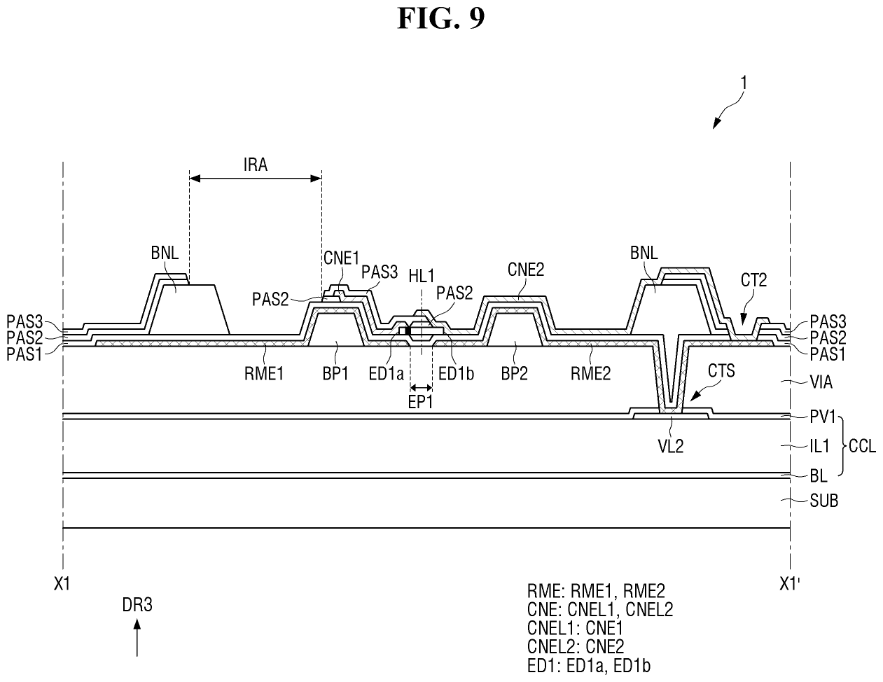

The second alignment electrode RME2 may be electrically connected to the circuit element layer CCL (see FIG. 9) to be described later through a second electrode contact hole CTS. The second alignment electrode RME2 may be applied with the above-described second power voltage through the second electrode contact hole CTS.

The first electrode contact hole CTD and the second electrode contact hole CTS may not overlap the emission area EMA. In some embodiments, the first electrode contact hole CTD and the second electrode contact hole CTS may be disposed to overlap the external bank BNL in a plan view, but are not limited thereto. For example, the first electrode contact hole CTD and the second electrode contact hole CTS may be disposed on the sub-region SA. FIGS. 4 and 6 illustrate that the first electrode contact hole CTD and the second electrode contact hole CTS overlap the external bank BNL.

As illustrated in FIG. 6, multiple internal banks BP may be disposed under each of the alignment electrodes RME. The internal banks BP may be disposed in the emission area EMA of the sub-pixel SPXn. Each of the internal banks BP may include a first internal bank BP1, a second internal bank BP2, and a third internal bank BP3 having a rectangular planar shape extending in the second direction DR2. The first internal bank BP1, the second internal bank BP2, and the third internal bank BP3 may be disposed to be spaced apart from each other in the first direction DR1.

The first internal bank BP1 may be disposed under the first alignment electrode RME1 in the emission area EMA, the second internal bank BP2 may be disposed under the second alignment electrode RME2 in the emission area EMA, and the third internal bank BP3 may be disposed under the third alignment electrode RME3 in the emission area EMA.

In some embodiments, the alignment electrodes RME may completely cover each internal bank BP disposed under each alignment electrode RME in the emission area EMA in a plan view, but are not limited thereto. For example, the alignment electrodes RME may partially cover each internal bank BP disposed under each alignment electrode RME in the emission area EMA. FIG. 6 illustrates that the alignment electrodes RME completely cover each internal bank BP disposed under each alignment electrode RME in the emission area EMA.

The alignment electrodes RME may be spaced apart from each other in the first direction DR1 to provide a space in which the light emitting element ED is disposed. For example, the light emitting elements ED may be disposed on a first narrow passage EP1 defined as a separation space between the first alignment electrode RME1 and the second alignment electrode RME2, and a second narrow passage EP2 defined as a separation space between the second alignment electrode RME2 and the third alignment electrode RME3.

Referring to FIG. 5, the light emitting element ED may be a light emitting diode. For example, the light emitting element ED may be an inorganic light emitting diode that has a nanometer or micrometer size, and may be made of an inorganic material. The light emitting element ED may be aligned between two electrodes having polarity in case that an electric field is formed in a specific direction between two electrodes facing each other.

The light emitting element ED according to one embodiment may have a shape elongated in one direction. The light emitting element ED may have a shape of a cylinder, a rod, a wire, a tube, or the like. However, the shape of the light emitting element ED is not limited thereto, and the light emitting element ED may have a polygonal prism shape such as a regular cube, a rectangular parallelepiped, and a hexagonal prism, or may have various shapes such as a shape elongated in one direction and having an outer surface partially inclined.

The light emitting element ED may include a semiconductor layer doped with a conductivity type (e.g., p-type or n-type) dopant. The semiconductor layer may emit light of a specific wavelength band by receiving an electrical signal applied from an external power source. The light emitting element ED may include a first semiconductor layer 31, a second semiconductor layer 32, a light emitting layer 36, an electrode layer 37, and an insulating film 38.

The first semiconductor layer 31 may be an n-type semiconductor. The first semiconductor layer 31 may include a semiconductor material having a chemical formula of AlₓGa_{y}In_{1-x-y}N (0≤x≤1, 0≤y≤1, 0≤x+y≤1). For example, the first semiconductor layer 31 may include at least one of AlGaInN, GaN, AlGaN, InGaN, AlN, and InN doped with an n-type dopant. The n-type dopant doped into the first semiconductor layer 31 may be Si, Ge, Sn, Se, or the like.

The second semiconductor layer 32 may be disposed on the first semiconductor layer 31 with the light emitting layer 36 therebetween. The second semiconductor layer 32 may be a p-type semiconductor, and the second semiconductor layer 32 may include a semiconductor material having a chemical formula of AlₓGa_{y}In_{1-x-y}N (0≤x≤1, 0≤y≤1, 0≤x+y≤1). For example, the second semiconductor layer 32 may include at least one of AlGaInN, GaN, AlGaN, InGaN, AlN, and InN doped with a p-type dopant. The p-type dopant doped into the second semiconductor layer 32 may be Mg, Zn, Ca, Ba, or the like.

Accordingly, both ends of the light emitting element ED may have different polarities. Hereinafter, for simplicity of description, among both ends of the light emitting element ED, an end to which the second semiconductor layer 32 is adjacent is referred to as a “first end,” and another end to which the first semiconductor layer 31 is adjacent is referred to as a “second end.” The first end of the light emitting element ED may be positioned opposite to the second end.

The first end and the second end of the light emitting element ED may have different polarities. The first ends of the light emitting elements ED may have the same polarity, and the second ends of the light emitting elements ED may have the same polarity.

Although it is illustrated in the drawing that the first semiconductor layer 31 and the second semiconductor layer 32 are configured as one layer, the disclosure is not limited thereto. Depending on the material of the light emitting layer 36, the first semiconductor layer 31 and the second semiconductor layer 32 may include a larger number of layers, such as a cladding layer or a tensile strain barrier reducing (TSBR) layer. For example, the light emitting element ED may include another semiconductor layer disposed between the first semiconductor layer 31 and the light emitting layer 36 or between the second semiconductor layer 32 and the light emitting layer 36. The semiconductor layer disposed between the first semiconductor layer 31 and the light emitting layer 36 may include one or more of AlGaInN, GaN, AlGaN, InGaN, AlN, InN and SLs doped with an n-type dopant, and the semiconductor layer disposed between the second semiconductor layer 32 and the light emitting layer 36 may include one or more of AlGaInN, GaN, AlGaN, InGaN, AlN and InN doped with a p-type dopant.

The light emitting layer 36 may be disposed between the first semiconductor layer 31 and the second semiconductor layer 32. The light emitting layer 36 may include a material having a single or multiple quantum well structure. In case that the light emitting layer 36 includes a multiple quantum well structure, multiple quantum layers and well layers may be alternately stacked each other. The light emitting layer 36 may emit light by coupling of electron-hole pairs according to an electrical signal applied through the first semiconductor layer 31 and the second semiconductor layer 32. The light emitting layer 36 may include a material such as AlGaN, AlGaInN, or InGaN. For example, in case that the light emitting layer 36 has a multiple quantum well structure in which quantum layers and well layers are alternately stacked each other, the quantum layer may include a material such as AlGaN or AlGaInN, and the well layer may include a material such as GaN or AlInN.

The light emitting layer 36 may have a structure in which semiconductor materials having a large band gap energy and semiconductor materials having a small band gap energy are alternately stacked each other, and may include group III to V semiconductor materials depending on the wavelength band of the emitted light. The light emitted by the light emitting layer 36 is not limited to the light of the blue wavelength band, and the light emitting layer 36 may emit light of a red or green wavelength band in some embodiments.

The electrode layer 37 may be an ohmic connection electrode. However, the disclosure is not limited thereto, and it may be a Schottky connection electrode. The light emitting element ED may include at least one electrode layer 37. The light emitting element ED may include one or more electrode layers 37, but the disclosure is not limited thereto, and the electrode layer 37 may be omitted.

In the display device 1, in case that the light emitting element ED is electrically connected to an electrode or a connection electrode, the electrode layer 37 may reduce the resistance between the light emitting element ED and the electrode or connection electrode. The electrode layer 37 may include a conductive metal. For example, the electrode layer 37 may include at least one of aluminum (Al), titanium (Ti), indium (In), gold (Au), silver (Ag), ITO, IZO, and ITZO. With the above-described configuration, both ends of each of the light emitting elements ED may have different polarities.

The insulating film 38 may be arranged to surround the outer surfaces of the semiconductor layers and electrode layers described above. For example, the insulating film 38 may be disposed to surround at least the outer surface of the light emitting layer 36, and may be formed to expose both ends of the light emitting element ED in the longitudinal direction. Further, in a cross-sectional view, the insulating film 38 may have a top surface, which is rounded in a region adjacent to at least one end of the light emitting element ED.

The insulating film 38 may include at least one material having insulating properties, for example, silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), or titanium oxide (TiOₓ). It is illustrated in the drawing that the insulating film 38 is formed as a single layer, but the disclosure is not limited thereto. In some embodiments, the insulating film 38 may be formed in a multilayer structure having multiple layers stacked each other therein.

The insulating film 38 may perform a function of protecting the semiconductor layers and the electrode layer of the light emitting element ED. The insulating film 38 may prevent an electrical short circuit that is likely to occur at the light emitting layer 36 in case that an electrode to which an electrical signal is transmitted is in direct contact with the light emitting element ED. The insulating film 38 may prevent a decrease in luminous efficiency of the light emitting element ED.

The insulating film 38 may have an outer surface which is surface-treated. The light emitting elements ED may be aligned by spraying the ink in which the light emitting elements ED are dispersed on the electrodes. The surface of the insulating film 38 may be treated to have a hydrophobic property or hydrophilic property in order to keep the light emitting elements ED in the dispersed state without being aggregated with other adjacent light emitting elements ED in the ink.

Referring to FIG. 6, the light emitting element ED may include a first light emitting element ED1 disposed on the first narrow passage EP1 and a second light emitting element ED2 disposed on the second narrow passage EP2, in the emission area EMA of each sub-pixel SPXn.

A hatched portion is illustrated in each of the light emitting elements ED illustrated in FIG. 6, for example, the first light emitting element ED1 and the second light emitting element ED2. The hatched portion in each of the light emitting elements ED may be the light emitting layer 36 illustrated in FIG. 5. Accordingly, the end adjacent to the hatched portion of each of the first light emitting element ED1 and the second light emitting element ED2 may be the above-described first end, and the opposite end thereof may be the second end.

The first light emitting element ED1 may be arranged to extend in the first direction DR1 to be oriented such that the first end is disposed on the first alignment electrode RME1 and the second end is disposed on the second alignment electrode RME2. Multiple first light emitting elements ED1 may be disposed and arranged side by side on the first narrow passage EP1 in the second direction DR2.

The second light emitting element ED2 may be arranged to extend in the first direction DR1 to be oriented such that the first end is disposed on the third alignment electrode RME3 and the second end is disposed on the second alignment electrode RME2. Multiple second light emitting elements ED2 may be disposed and arranged in the second direction DR2 on the second narrow passage EP2. Accordingly, the second end of the first light emitting element ED1 may be oriented to face the second end of the second light emitting element ED2.

In the specification, it may be understood that the orientation of the light emitting element ED is divided according to a relative position of the first end or the second end of the light emitting element ED. For example, in the display device 1 according to one embodiment, the first light emitting element ED1 may have the first end facing the other side of the first direction DR1 and the second end facing one side of the first direction, whereas the second light emitting element ED2 may have the first end facing one side of the first direction DR1 and the second end facing the other side of the first direction DR1, so that it may be understood that the first light emitting element ED1 and the second light emitting element ED2 have opposite orientations.

The fact that the orientation of the first light emitting element ED1 and the orientation of the second light emitting element ED2 are different from each other may be due to the fact that the first end and the second end of the light emitting element ED are oriented differently according to the type of the alignment signal applied to the alignment electrode RME in the process of manufacturing the display device 1 according to one embodiment. A detailed description thereof will be provided later.

Referring to FIGS. 4 and 6, the connection electrode CNE may be disposed on the light emitting elements ED. The connection electrode CNE may include a first connection electrode CNE1, a second connection electrode CNE2, a third connection electrode CNE3, and a fourth connection electrode CNE4 that are spaced apart from each other and sequentially arranged in the first direction DR1.

The first connection electrode CNE1, the second connection electrode CNE2, the third connection electrode CNE3, and the fourth connection electrode CNE4 may be spaced apart from each other and sequentially arranged in the first direction DR1. For example, the second connection electrode CNE2 may be disposed on one side of the first connection electrode CNE1 in the first direction DR1, the third connection electrode CNE3 may be disposed on one side of the second connection electrode CNE2 in the first direction DR1, and the fourth connection electrode CNE4 may be disposed on one side of the third connection electrode CNE3 in the first direction DR1.

The connection electrode CNE may include a first connection electrode layer CNEL1 including the first connection electrode CNE1 and the fourth connection electrode CNE4, and a second connection electrode layer CNEL2 including the second connection electrode CNE2 and the third connection electrode CNE3. The first connection electrode layer CNEL1 and the second connection electrode layer CNEL2 may be distinguished according to a stacking order. For example, in the display device manufacturing process, the first connection electrode layer CNEL1 may be formed before the second connection electrode layer CNEL2.

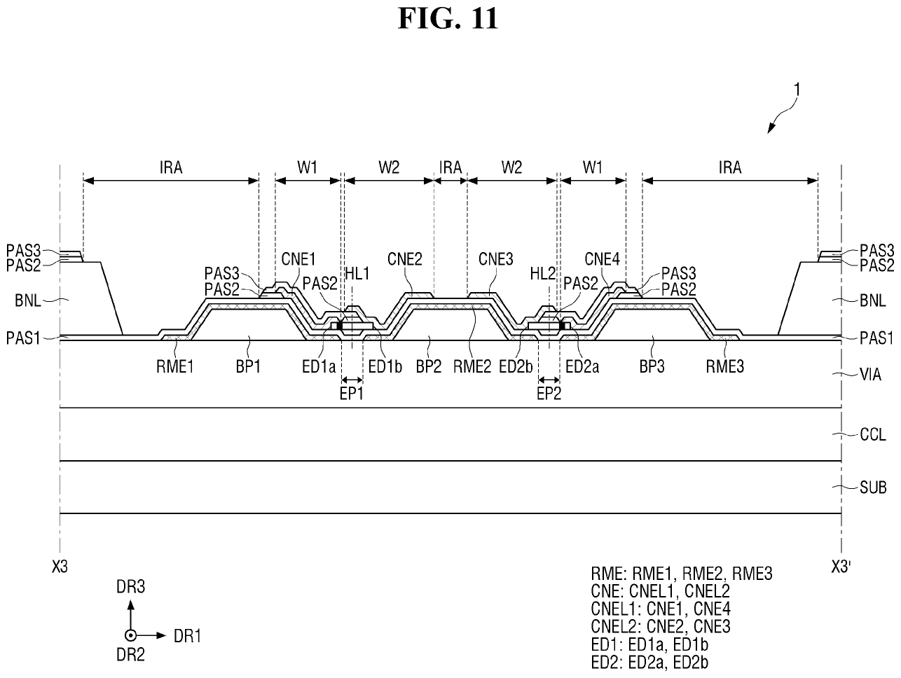

For example, a second insulating layer PAS2 may be disposed under the first connection electrode layer CNEL1 as illustrated in FIG. 11, and the third insulating layer PAS3 may be disposed between the first connection electrode layer CNEL1 and the second connection electrode layer CNEL2 as illustrated in FIG. 11. In other words, the first connection electrode layer CNEL1 may be disposed on the second insulating layer PAS2, the third insulating layer PAS3 may be disposed on the first connection electrode layer CNEL1, and the second connection electrode layer CNEL2 may be disposed on the third insulating layer PAS3.

Accordingly, the connection electrode CNE disposed in one sub-pixel SPXn of the display device 1 according to one embodiment may have a structure in which two first connection electrode layers CNEL1 are disposed to be spaced apart from each other on the outer side, and two second connection electrode layers CNEL2 are disposed to be spaced apart from each other in a separation space between two first connection electrode layers CNEL1.

The second insulating layer PAS2 disposed under the first connection electrode layer CNEL1 may be disposed on the light emitting element ED to fix the light emitting elements ED. The second insulating layer PAS2 may be patterned in a portion adjacent to the emission area EMA. For example, the second insulating layer PAS2 may be a patterned insulating layer, and may include a portion extending in the second direction DR2 to cover a portion of the first internal bank BP1, a portion extending in the second direction DR2 to cover a portion of the second internal bank BP2, a portion extending in the second direction DR2 to cover the central portions of the light emitting elements ED arranged in the second direction DR2, and a portion covering the edge of the emission area EMA. The respective portions of the second insulating layer PAS2 may be disposed to be spaced apart from each other, and the separation space disposed between the respective portions may be the portion on which the second insulating layer PAS2 is not disposed.

The portion of the second insulating layer PAS2 extending in the second direction DR2 and covering the central portions of the light emitting elements ED arranged in the second direction DR2 may expose both ends of the light emitting elements ED. For example, the second insulating layer PAS2 may expose the first end and the second end of the first light emitting element ED1 and expose the first end and the second end of the second light emitting element ED2.

The portion of the second insulating layer PAS2 covering the edge of the emission area EMA may be formed to surround the edge of the area wider than the emission area EMA. This may be to prevent light emitted from the light emitting element ED from being refracted. A description thereof will be given later.

The first connection electrode layer CNEL1 disposed on the second insulating layer PAS2 may include the first connection electrode CNE1 and the fourth connection electrode CNE4. The first connection electrode layer CNEL1 may have a first width W1 in the first direction DR1. The first connection electrode layer CNEL1 may include the connection electrodes CNE in contact with the first end of the light emitting element ED. For example, in the emission area EMA, each of the first connection electrode CNE1 and the fourth connection electrode CNE4 may have the first width W1 in the first direction DR1.

In some embodiments, the first connection electrode CNE1 and the fourth connection electrode CNE4 may have the same width, but the disclosure is not limited thereto. For example, the first connection electrode CNE1 and the fourth connection electrode CNE4 may have different widths. FIG. 6 illustrates that the first connection electrode CNE1 and the fourth connection electrode CNE4 have the same first width W1.

The first connection electrode CNE1 of the first connection electrode layer CNEL1 may be disposed on the first alignment electrode RME1 in the emission area EMA. The first connection electrode CNE1 may generally have the first width W1 in the first direction DR1 in the emission area EMA and may have a shape extending in the second direction DR2.

In some embodiments, the first connection electrode CNE1 may have a shape that is bent at least once at a portion that does not overlap the emission area EMA, but is not limited thereto. FIG. 6 illustrates that the first connection electrode CNE1 extends in the emission area EMA in the second direction DR2 and has a shape bent to extend in the first direction DR1 on the external bank BNL disposed on one side of the emission area EMA in the second direction DR2.

The first connection electrode CNE1 may be in contact with the first end of the first light emitting element ED1 in the emission area EMA. For example, the first connection electrode CNE1 may have the first width W1 in the first direction DR1 in the emission area EMA and extend in the second direction DR2, and may be in contact with the first ends of the first light emitting elements ED1 arranged in the second direction DR2 in the first narrow passage EP1.

The first connection electrode CNE1 may be bent to one side of the first direction DR1 on the external bank BNL disposed on one side of the emission area EMA in the second direction DR2 to be electrically connected to the third connection electrode CNE3 to be described later.

The first connection electrode CNE1 may partially overlap the first narrow passage EP1 in the emission area EMA, but may not overlap a central portion HL1 of the first narrow passage EP1 in a plan view. The central portion HL1 of the first narrow passage EP1 may be a half point of the width of the first narrow passage EP1 in the first direction DR1. For example, the linear distance in the first direction DR1 from the central portion HL1 of the first narrow passage EP1 to the first alignment electrode RME1 may be the same as the linear distance in the first direction DR1 from the central portion HL1 of the first narrow passage EP1 to the second alignment electrode RME2.

The fourth connection electrode CNE4 of the first connection electrode layer CNEL1 may be disposed on the third alignment electrode RME3. The fourth connection electrode CNE4 may generally have the first width W1 in the first direction DR1 and may have a shape extending in the second direction DR2.

A portion of the fourth connection electrode CNE4 may be connected to the third alignment electrode RME3 through a first contact portion CT1 penetrating the second insulating layer PAS2 as illustrated in FIG. 7 in an area that does not overlap the emission area EMA. Accordingly, the fourth connection electrode CNE4 may be supplied with the above-described first power voltage through the third alignment electrode RME3.

Another portion of the fourth connection electrode CNE4 may be in contact with the first end of the second light emitting element ED2 in the emission area EMA. For example, the another portion of the fourth connection electrode CNE4 may extend in the second direction DR2 in the emission area EMA, and may be in contact with the first ends of the second light emitting elements ED2 arranged in the second direction DR2 in the second narrow passage EP2.

The fourth connection electrode CNE4 may partially overlap the second narrow passage EP2 in the emission area EMA, but may not overlap a central portion HL2 of the second narrow passage EP2 in a plan view. The central portion HL2 of the second narrow passage EP2 may be a half point of the width of the second narrow passage EP2 in the first direction DR1. For example, the linear distance in the first direction DR1 from the central portion HL2 of the second narrow passage EP2 to the second alignment electrode RME2 may be the same as the linear distance in the first direction DR1 from the central portion HL2 of the second narrow passage EP2 to the third alignment electrode RME3.

The third insulating layer PAS3 disposed on the first connection electrode layer CNEL1 may serve to electrically insulate the first connection electrode layer CNEL1 from the second connection electrode layer CNEL2. The third insulating layer PAS3 may be patterned in a portion adjacent to the emission area EMA. For example, the third insulating layer PAS3 may include a portion extending in the second direction DR2 to cover the first end of the first light emitting element ED1 and expose the second end, a portion extending in the second direction DR2 to cover the first end of the second light emitting element ED2 and expose the second end, and a portion covering the edge of the emission area EMA. In each portion of the third insulating layer PAS3, one portion may be partially spaced apart from other portions while the other portions are formed by being connected to each other, and the separation space disposed between the respective portions may be the portion on which the third insulating layer PAS3 is not disposed.

The portion of the third insulating layer PAS3 extending in the second direction DR2 to cover the first end of the first light emitting element ED1 and exposing the second end may have a shape protruding toward the other side of the second direction DR2 from a portion covering the edge of the emission area EMA toward the emission area EMA.

The portion of the third insulating layer PAS3 extending in the second direction DR2 to cover the first end of the second light emitting element ED2 and exposing the second end may have a shape protruding toward one side of the second direction DR2 from a portion covering the edge of the emission area EMA toward the emission area EMA.

The portion of the third insulating layer PAS3 covering the edge of the emission area EMA may be formed to surround the edge of the area wider than the emission area EMA. This may be to prevent light emitted from the light emitting element ED from being refracted. A description thereof will be given later.

A portion in which the separation space disposed between the respective portions of the third insulating layer PAS3 and the separation space disposed between the respective portions of the above-described second insulating layer PAS2 overlap may be defined as a low refractive area IRA. For example, the low refractive area IRA may be an area in which both the second insulating layer PAS2 and the third insulating layer PAS3 are not disposed. A detailed description of the low refractive area IRA will be provided later.

The second connection electrode layer CNEL2 disposed on the third insulating layer PAS3 may include the second connection electrode CNE2 and the third connection electrode CNE3. The second connection electrode layer CNEL2 may have a second width W2 in the first direction DR1. The second connection electrode layer CNEL2 may include the connection electrodes CNE in contact with the second end of the light emitting element ED. For example, in the emission area EMA, each of the second connection electrode CNE2 and the third connection electrode CNE3 may have the second width W2 in the first direction DR1. The second width W2 may be greater than the first width W1. Accordingly, the second connection electrode layer CNEL2 may secure contact with the second end of the light emitting element ED although the light emitting element ED is not properly aligned in a display device manufacturing process to be described later. A detailed description thereof will be given later.

In some embodiments, the second connection electrode CNE2 and the third connection electrode CNE3 may have the same width, but the disclosure is not limited thereto. For example, the second connection electrode CNE2 and the third connection electrode CNE3 may have different widths. FIG. 6 illustrates that the second connection electrode CNE2 and the third connection electrode CNE3 have the same second width W2.

The second connection electrode CNE2 of the second connection electrode layer CNEL2 may be disposed on the other side of the second alignment electrode RME2 in the first direction DR1. The second connection electrode CNE2 may generally have the second width W2 in the first direction DR1 and may have a shape extending in the second direction DR2.

A portion of the second connection electrode CNE2 may be connected to the second alignment electrode RME2 through a second contact portion CT2 penetrating the second insulating layer PAS2 and the third insulating layer PAS3 as illustrated in FIGS. 7 and 8 in an area that does not overlap the emission area EMA. Accordingly, the second connection electrode CNE2 may be supplied with the above-described second power voltage through the second alignment electrode RME2.

Another portion of the second connection electrode CNE2 may be in contact with the second end of the first light emitting element ED1 in the emission area EMA. For example, a portion of the second connection electrode CNE2 may extend in the second direction DR2 in the emission area EMA, and may be in contact with the second ends of the first light emitting elements ED1 arranged in the second direction DR2 in the first narrow passage EP1.

The second connection electrode CNE2 may partially overlap the first narrow passage EP1 in the emission area EMA to cover the central portion HL1 of the first narrow passage EP1 in a plan view. For example, in the first narrow passage EP1, the second connection electrode CNE2 may overlap a point beyond the central portion HL1 of the first narrow passage EP1 to completely cover the central portion HL1 of the first narrow passage EP1. Accordingly, contact between the second connection electrode CNE2 and the second end of the first light emitting element ED1 may be secured although the first light emitting element ED1 is not properly aligned in a display device manufacturing process to be described later. A detailed description thereof will be given later.

The third connection electrode CNE3 of the second connection electrode layer CNEL2 may be disposed on the second alignment electrode RME2 in the emission area EMA. The third connection electrode CNE3 may generally have the second width W2 in the first direction DR1 in the emission area EMA and may have a shape extending in the second direction DR2.

In some embodiments, the third connection electrode CNE3 may have a shape that is bent at least once at a portion that does not overlap the emission area EMA, but is not limited thereto. FIG. 6 illustrates that the third connection electrode CNE3 extends in the emission area EMA in the second direction DR2 and has a shape bent to extend in the first direction DR1 on the external bank BNL disposed on one side of the emission area EMA in the second direction DR2.

The third connection electrode CNE3 may be in contact with the second end of the second light emitting element ED2 in the emission area EMA. For example, the third connection electrode CNE3 may have the second width W2 in the first direction DR1 in the emission area EMA and extend in the second direction DR2, and may be in contact with the second ends of the second light emitting elements ED2 arranged in the second direction DR2.

The third connection electrode CNE3 may be bent to the other side of the first direction DR1 on the external bank BNL disposed on one side of the emission area EMA in the second direction DR2 to be electrically connected to the first connection electrode CNE1 through a node contact portion CTN penetrating the third insulating layer PAS3 as illustrated in FIG. 8.

The third connection electrode CNE3 may partially overlap the second narrow passage EP2 in the emission area EMA to cover the central portion HL2 of the second narrow passage EP2. For example, in the second narrow passage EP2, the third connection electrode CNE3 may overlap a point beyond the central portion HL2 of the second narrow passage EP2 to completely cover the central portion HL2 of the second narrow passage EP2. Accordingly, contact between the third connection electrode CNE3 and the second end of the second light emitting element ED2 may be secured although the second light emitting element ED2 is not properly aligned in a display device manufacturing process to be described later. A detailed description thereof will be given later.

Hereinafter, a stacked structure of elements constituting the display device 1 according to one embodiment will be described.

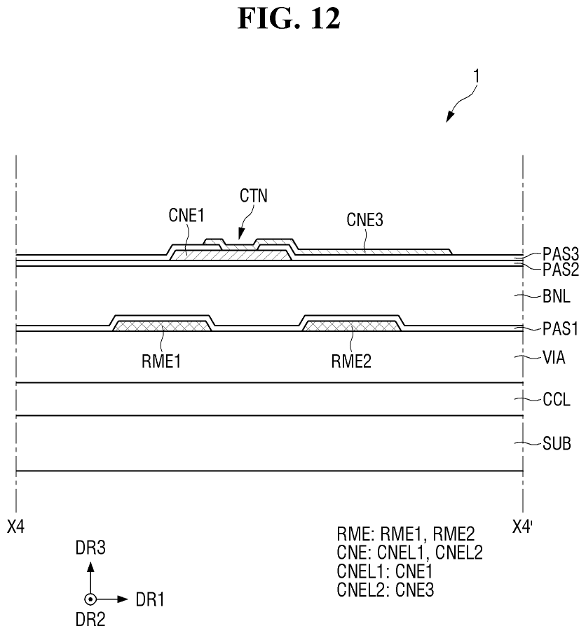

FIG. 9 is a schematic cross-sectional view of a pixel taken along line X1-X1′ of FIG. 6. FIG. 10 is a schematic cross-sectional view of a pixel taken along line X2-X2′ of FIGS. 6 to 8. FIG. 11 is a schematic cross-sectional view of a pixel taken along line X3-X3′ of FIGS. 6 to 8. FIG. 12 is a schematic cross-sectional view of a pixel taken along line X4-X4′ of FIGS. 6 to 8.

FIG. 9 illustrates a cross section traversing the second electrode contact hole CTS, the second contact portion CT2, and the first light emitting element ED1, FIG. 10 illustrates a cross section traversing the first electrode contact hole CTD, the first contact portion CT1, and the second light emitting element ED2, FIG. 11 illustrates a cross section traversing the first light emitting element ED1 and the second light emitting element ED2, and FIG. 12 illustrates a cross section traversing the node contact portion CTN.

A cross-sectional structure of the display device 1 according to one embodiment will be described with reference to FIGS. 9 to 12 in conjunction with FIGS. 6 to 8. The display device 1 may include a substrate SUB, and a semiconductor layer, multiple conductive layers, and multiple insulating layers, disposed on the substrate SUB. As described above, the display device 1 may include multiple electrodes RME, the light emitting element ED, and the connection electrode CNE. The semiconductor layer, the conductive layers, and the insulating layers may each constitute a circuit element layer of the display device 1.

The substrate SUB may be made of an insulating material such as glass, quartz, or a polymer resin. The substrate SUB may be a rigid substrate, or may be a flexible substrate which can be bent, folded, or rolled.

The circuit element layer may be disposed on the substrate SUB. In the circuit element layer, various wires that transmit electrical signals to the light emitting element ED disposed on the substrate SUB may be disposed. The circuit element layer CCL may include a first conductive layer, a semiconductor layer, a second conductive layer, a third conductive layer, and the like as the conductive layers as illustrated in FIGS. 9 to 10, and may include a buffer layer BL, a first gate insulating layer G1, a first interlayer insulating layer ILL a first passivation layer PV1, and the like as the insulating layers.

A first conductive layer may be disposed on the substrate SUB. The first conductive layer may include a lower metal layer BML that is disposed to overlap a first active layer ACT1 of a first transistor T1. The lower metal layer BML may prevent light from entering the first active layer ACT1 of the first transistor T1, and/or may be electrically connected to the first active layer ACT1 to stabilize electrical characteristics of the first transistor T1. However, the lower metal layer BML may be omitted.

The buffer layer BL may be disposed on the lower metal layer BML and the substrate SUB. The buffer layer BL may be formed on the substrate SUB to protect the transistors of the pixel PX from moisture permeating through the substrate SUB susceptible to moisture permeation, and may perform a surface planarization function.

The semiconductor layer may be disposed on the buffer layer BL. The semiconductor layer may include the first active layer ACT1 of the first transistor T1 and a second active layer ACT2 of the second transistor T2. The first active layer ACT1 and the second active layer ACT2 may be disposed to partially overlap a first gate electrode G1 and a second gate electrode G2 of a second conductive layer respectively to be described later, respectively.

The semiconductor layer may include polycrystalline silicon, monocrystalline silicon, oxide semiconductor, and the like. In another embodiment, the semiconductor layer may include polycrystalline silicon. The oxide semiconductor may be an oxide semiconductor containing indium (In). For example, the oxide semiconductor may include at least one of indium tin oxide (ITO), indium zinc oxide (IZO), indium gallium oxide (IGO), indium zinc tin oxide (IZTO), indium gallium tin oxide (IGTO), indium gallium zinc oxide (IGZO), and indium gallium zinc tin oxide (IGZTO).

Although it is illustrated in the drawing that the first transistor T1 and the second transistor T2 are disposed in the pixel PX of the display device 1, the disclosure is not limited thereto, and the display device 1 may include a larger number of transistors.

A first gate insulating layer G1 may be disposed on the semiconductor layer in the display area DA. The first gate insulating layer G1 may serve as a gate insulating layer of each of the transistors T1 and T2. Although it is illustrated in the drawing that the first gate insulating layer G1 is patterned together with the gate electrodes G1 and G2 of the second conductive layer to be described later and partially disposed between the second conductive layer and the active layers ACT1 and ACT2 of the semiconductor layer. However, the disclosure is not limited thereto. In some embodiments, the first gate insulating layer G1 may be entirely disposed on the buffer layer BL.

The second conductive layer may be disposed on the first gate insulating layer G1. The second conductive layer may include a first gate electrode G1 of the first transistor T1 and a second gate electrode G2 of the second transistor T2. The first gate electrode G1 may be disposed to overlap the channel region of the first active layer ACT1 in a third direction DR3 that is a thickness direction, and the second gate electrode G2 may be disposed to overlap the channel region of the second active layer ACT2 in the third direction DR3 that is the thickness direction.

A first interlayer insulating layer IL1 may be disposed on the second conductive layer. The first interlayer insulating layer IL1 may function as an insulating film between the second conductive layer and other layers disposed thereon, and may protect the second conductive layer.

A third conductive layer may be disposed on the first interlayer insulating layer IL1. The third conductive layer may include the first voltage line VL1 and the second voltage line VL2, a first conductive pattern CDP1, a source electrode S1 and a drain electrode D1 of the transistor T1, and a source electrode S2 and a drain electrode D2 of the transistor T2 that are disposed in the display area DA.

The first voltage line VL1 may be applied with a high potential voltage (or a first power voltage) transmitted to the first alignment electrode RME1, and the second voltage line VL2 may be applied with a low potential voltage (or a second power voltage) transmitted to the second alignment electrode RME2. The first voltage line VL1 may partially be in contact with the first active layer ACT1 of the first transistor T1 through a contact hole that penetrates the first interlayer insulating layer IL1. The first voltage line VL1 may serve as a first drain electrode D1 of the first transistor T1. The first voltage line VL1 may be connected (i.e., directly connected) to the first alignment electrode RME1, and the second voltage line VL2 may be connected (i.e., directly connected) to the second alignment electrode RME2.

The first conductive pattern CDP1 may be in contact with the first active layer ACT1 of the first transistor T1 through the contact hole penetrating the first interlayer insulating layer IL1. The first conductive pattern CDP1 may be in contact with the lower metal layer BML through another contact hole penetrating the first interlayer insulating layer IL1 and the buffer layer BL. The first conductive pattern CDP1 may serve as a first source electrode S1 of the first transistor T1. Further, the first conductive pattern CDP1 may be connected to the first electrode RME1 or the first connection electrode CNE1 to be described later. The first transistor T1 may transmit the first power voltage applied from the first voltage line VL1 to the first electrode RME1 or the first connection electrode CNE1.

The second source electrode S2 and the second drain electrode D2 may be in contact with the second active layer ACT2 of the second transistor T2 through the contact holes penetrating the first interlayer insulating layer IL1.

A first passivation layer PV1 may be disposed on the third conductive layer. The first passivation layer PV1 may function as an insulating layer between the third conductive layer and other layers and may protect the third conductive layer.

The buffer layer BL, the first gate insulating layer G1, the first interlayer insulating layer ILL and the first passivation layer PV1 described above may be formed of multiple inorganic layers stacked each other in an alternating manner. For example, the buffer layer BL, the first gate insulating layer G1, the first interlayer insulating layer ILL and the first passivation layer PV1 may be formed as a double layer formed by stacking, or a multilayer formed by alternately stacking, inorganic layers including at least one of silicon oxide (SiOₓ), silicon nitride (SiNₓ), or silicon oxynitride (SiOₓN_{y}) each other.

A via insulating layer VIA may be disposed on the circuit element layer CCL. For example, the via insulating layer VIA may be disposed on the first passivation layer PV1 of the circuit element layer CCL. The via insulating layer VIA may include an organic insulating material such as polyimide, and may form a flat top surface while a height difference due to various wires inside the circuit element layer is compensated.

The internal bank BP may be disposed on the top surface of the via insulating layer VIA. In other words, the via insulating layer VIA and the internal bank BP may be in direct contact.

The internal banks BP may be disposed on the via insulating layer VIA. The internal bank BP may have a side surface that is inclined or curved with a certain curvature, and the light emitted from the light emitting element ED may be reflected from the alignment electrode RME disposed on the internal bank BP and be emitted in the third direction DR3. The internal banks BP may include an organic insulating material made of a transparent material such as polyimide, but is not limited thereto. For example, the internal banks BP may include a colored dye such as a black pigment.

The alignment electrodes RME may be disposed on the internal bank BP and the via insulating layer VIA.

As illustrated in FIG. 11, the first alignment electrode RME1 may be disposed on the first internal bank BP1 to extend in a direction toward the second internal bank BP2 in a cross-sectional view, the second alignment electrode RME2 may be disposed on the second internal bank BP2 to extend in a direction toward the first internal bank BP1 and a direction toward the third internal bank BP3 in a cross-sectional view, and the third alignment electrode RME3 may be disposed on the third internal bank BP3 to extend in a direction toward the second internal bank BP2 in a cross-sectional view.

A distance between the first alignment electrode RME1, the second alignment electrode RME2, and the third alignment electrode RME3 spaced apart from each other may be narrower than a distance between the first internal bank BP1, the second internal bank BP2, and the third internal bank BP3 spaced apart from each other. For example, at least a partial area of the first alignment electrode RME1, the second alignment electrode RME2, and the third alignment electrode RME3 may be directly disposed on the via insulating layer VIA and be disposed on the same plane.

The third alignment electrode RME3 may be in contact with the first conductive pattern CDP1 through the first electrode contact hole CTD penetrating the via insulating layer VIA and the first passivation layer PV1. The second alignment electrode RME2 may be in contact with the second voltage line VL2 through the second electrode contact hole CTS penetrating the via insulating layer VIA and the first passivation layer PV1.

The alignment electrode RME may reflect light emitted from the light emitting element ED. For example, the light emitting elements ED may be disposed between the internal banks BP to emit light in both end directions, and the emitted light may be directed to the alignment electrodes RME disposed on the internal banks BP. Accordingly, the light emitted from the light emitting element ED may be reflected by the alignment electrode RME to be emitted in the third direction DR3.

The alignment electrodes RME may include a conductive material having high reflectivity. For example, the alignment electrodes RME may include a metal such as silver (Ag), copper (Cu), or aluminum (Al), or may include an alloy including aluminum (Al), nickel (Ni), lanthanum (La), or the like. For example, the electrodes RME may have a structure in which a metal layer such as titanium (Ti), molybdenum (Mo), and niobium (Nb) and the alloy are stacked each other. In some embodiments, the alignment electrodes RME may be formed as a double layer or a multilayer formed by stacking metal layers made of an alloy including aluminum (Al), titanium (Ti), molybdenum (Mo), or niobium (Nb) each other.

However, the disclosure is not limited thereto, and each alignment electrode RME may include a transparent conductive material. For example, each alignment electrode RME may include a material such as ITO, IZO, and ITZO. In some embodiments, each of the alignment electrodes RME may have a structure in which at least one transparent conductive material and at least one metal layer having high reflectivity are stacked each other, or may be formed as one layer including them. For example, each alignment electrode RME may have a stacked structure of ITO/Ag/ITO, ITO/Ag/IZO, ITO/Ag/ITZO/IZO, or the like. The alignment electrodes RME may be electrically connected to the light emitting element ED, and may reflect some of the lights emitted from the light emitting element ED in an upward direction of the substrate SUB.

The first insulating layer PAS1 may be disposed in the entire display area DA and may be disposed on the via insulating layer VIA and the alignment electrodes RME. The first insulating layer PAS1 may include an insulating material to protect the alignment electrodes RME and insulate alignment electrodes RME different from each other. The first insulating layer PAS1 may cover the alignment electrodes RME before the external bank BNL is formed, so that it is possible to prevent the alignment electrodes RME from being damaged in a process of forming the external bank BNL. The first insulating layer PAS1 may prevent the light emitting element ED disposed thereon from being damaged by direct contact with other members.

In an embodiment, the first insulating layer PAS1 may have stepped portions such that the top surface thereof is partially depressed between the alignment electrodes RME spaced apart in the first direction DR1. The light emitting element ED may be disposed on the top surface of the first insulating layer PAS1, where the stepped portions are formed, and thus a space may remain between the light emitting element ED and the first insulating layer PAS1.

The first insulating layer PAS1 may include the contact portions CT1 and CT2. The contact portions may be disposed to overlap different alignment electrodes RME, respectively. For example, the contact portions may include the first contact portion CT1 disposed to overlap the third alignment electrode RME3 in a plan view, and the second contact portion CT2 disposed to overlap the second alignment electrode RME2 in a plan view. The first contact portion CT1 and the second contact portion CT2 may penetrate the first insulating layer PAS1 to partially expose the top surface of the third alignment electrode RME3 or the second alignment electrode RME2 thereunder. Each of the first contact portion CT1 and the second contact portion CT2 may further penetrate some of other insulating layers disposed on the first insulating layer PAS1. The alignment electrode RME exposed by each of the contact portions may be in contact with the connection electrode CNE. The light emitting elements ED may be electrically connected to the circuit element layer CCL under the alignment electrode RME and the via insulating layer VIA by contact with the connection electrodes CNE, thereby emitting light of a specific wavelength band by being applied with an electrical signal.

The external bank BNL may be disposed on the first insulating layer PAS1. The external bank BNL may include portions extending in the first direction DR1 and the second direction DR2, and may surround the sub-pixels SPXn. The external bank BNL may surround and divide each sub-pixel SPXn, and may surround the outermost portion of the display area DA and divide the display area DA and the non-display area NDA.

The external bank BNL may have a height, similarly to the internal bank BP. In some embodiments, the height of the external bank BNL may be higher than the height of the internal bank BP, and a thickness thereof may be equal to or greater than the thickness of the internal bank BP. Accordingly, the external bank BNL may effectively prevent ink from overflowing into the adjacent pixels PX in the inkjet printing process during the manufacturing process of the display device 1. The external bank BNL may include an organic insulating material made of a transparent material such as polyimide in the same manner as the internal bank BP, but is not limited thereto. For example, the external bank BNL may include a colored dye such as a black pigment.

The second insulating layer PAS2 may be disposed on the light emitting elements ED, the first insulating layer PAS1, and the external bank BNL. The second insulating layer PAS2 may include a pattern portion disposed on the light emitting elements ED while extending in the second direction DR2 between the internal banks BP. The pattern portion may be disposed to partially surround the outer surface of the light emitting element ED, and may not cover both sides or both ends of the light emitting element ED. The pattern portion may form a linear or island-like pattern in each sub-pixel SPXn in a plan view as shown in FIG. 7. The pattern portion of the second insulating layer PAS2 may protect the light emitting element ED and fix the light emitting elements ED during a manufacturing process of the display device 1. Further, the second insulating layer PAS2 may be disposed to fill the space between the light emitting element ED and the first insulating layer PAS1 thereunder.

The second insulating layer PAS2 may include the contact portions CT1 and CT2. The contact portions may be disposed to overlap different alignment electrodes RME, respectively. For example, the contact portions may include the first contact portion CT1 disposed to overlap the third alignment electrode RME3 in a plan view and the second contact portion CT2 disposed to overlap the second alignment electrode RME2 in a plan view. The first contact portion CT1 and the second contact portion CT2 may penetrate the second insulating layer PAS2 to partially expose the top surface of the third alignment electrode RME3 or the second alignment electrode RME2 thereunder. Each of the first contact portion CT1 and the second contact portion CT2 may further penetrate some of other insulating layers disposed on the second insulating layer PAS2. The alignment electrode RME exposed by each of the contact portions may be in contact with the connection electrode CNE. The light emitting elements ED may be electrically connected to the circuit element layers CCL under the alignment electrode RME and the via insulating layer VIA by contact with the connection electrodes CNE, thereby emitting light of a specific wavelength band by being applied with an electrical signal.

The first connection electrode layer CNEL1 of the connection electrode CNE may be disposed on the second insulating layer PAS2. The first connection electrode CNE1 and the fourth connection electrode CNE4 of the first connection electrode layer CNEL1 may be disposed on the second insulating layer PAS2 to be in contact with the light emitting elements ED.

The first connection electrode CNE1 may partially overlap the first alignment electrode RME1 in the emission area EMA, and one side of the first connection electrode CNE1 in the first direction DR1 may be in contact with a first end ED1a of the first light emitting element ED1.

The patterned second insulating layer PAS2 on the internal bank BP1 may be disposed under the other side of the first connection electrode CNE1 in the first direction DR1. The second insulating layer PAS2 pattern disposed under the other side of the first connection electrode CNE1 in the first direction DR1 may effectively cover the other side surface of the first connection electrode CNE1 in the first direction DR1 together with the third insulating layer PAS3.

The fourth connection electrode CNE4 may partially overlap the third alignment electrode RME3 in the third direction DR3. The fourth connection electrode CNE4 may partially overlap the third alignment electrode RME3 in the emission area EMA, and the other side of the fourth connection electrode CNE4 in the first direction DR1 may be in contact with a first end ED2a of the second light emitting element ED2.

The patterned second insulating layer PAS2 on the internal bank BP3 may be disposed under one side of the fourth connection electrode CNE4 in the first direction DR1. The second insulating layer PAS2 pattern disposed under one side of the fourth connection electrode CNE4 in the first direction DR1 may effectively cover one side surface of the fourth connection electrode CNE4 in the first direction DR1 together with the third insulating layer PAS3.

As illustrated in FIG. 10, the fourth connection electrode CNE4 may be disposed to extend from the emission area EMA over the external bank BNL. The fourth connection electrode CNE4 may be in contact with the third alignment electrode RME3 through the first contact portion CT1 penetrating the first insulating layer PAS1 and the second insulating layer PAS2. Accordingly, the fourth connection electrode CNE4 may be electrically connected to the first transistor T1 to be applied with the first power voltage.

The third insulating layer PAS3 may be disposed on the second insulating layer PAS2, the first connection electrode layer CNEL1, and the external bank BNL. The third insulating layer PAS3 may form a linear or island-like pattern in a plan view as illustrated in FIG. 8 in the emission area EMA of each sub-pixel SPXn. The linear or island-like pattern formed by the third insulating layer PAS3 may not cover one end of the light emitting element ED. In other words, the third insulating layer PAS3 may not cover one ends of the light emitting elements ED with which the first connection electrode layer CNEL1 is not in contact in the emission area EMA.

The third insulating layer PAS3 may include the contact portions CT2 and CTN. For example, the contact portions may include the second contact portion CT2 disposed to overlap the second alignment electrode RME2 in a plan view and the node contact portion CTN disposed to overlap a portion of the first connection electrode CNE1 in a plan view. The second contact portion CT2 may penetrate the third insulating layer PAS3 to expose a portion of the top surface of the second alignment electrode RME2 thereunder, and the node contact portion CTN may expose a portion of the top surface of the first connection electrode CNE1.

The second alignment electrode RME2 exposed by the second contact portion CT2 may be in contact with the second connection electrode CNE2. Accordingly, the light emitting elements ED may be electrically connected to the circuit element layer CCL under the alignment electrode RME and the via insulating layer VIA by contact with the connection electrodes CNE, and may emit light of a specific wavelength band by being applied with an electrical signal.

The first connection electrode CNE1 of the first connection electrode layer CNEL1 exposed by the node contact portion CTN may be in contact with the third connection electrode CNE3 of the second connection electrode layer CNEL2. Accordingly, the first end ED1a of the first light emitting element ED1 and a second end ED2b of the second light emitting element ED2 may be electrically connected.

The second connection electrode layer CNEL2 of the connection electrode CNE may be disposed on the third insulating layer PAS3. The second connection electrode CNE2 and the third connection electrode CNE3 of the second connection electrode layer CNEL2 may be disposed on the third insulating layer PAS3 to be in contact with the light emitting elements ED.

The second connection electrode CNE2 may partially overlap the second alignment electrode RME2 in the third direction DR3. The second connection electrode CNE2 may partially overlap the other side of the second alignment electrode RME2 in the first direction DR1 to be in contact with a second end ED1b of the first light emitting element ED1.

As illustrated in FIG. 9, the second connection electrode CNE2 may partially overlap the second alignment electrode RME2 and may be disposed to extend from the emission area EMA over the external bank BNL. The second connection electrode CNE2 may be in contact with the second alignment electrode RME2 through the second contact portion CT2 penetrating the first insulating layer PAS1, the second insulating layer PAS2, and the third insulating layer PAS3. Accordingly, the second connection electrode CNE2 may be electrically connected to the second power line VL2 to be applied with the second power voltage.

As illustrated in FIG. 11, the second connection electrode CNE2 may extend in the first direction DR1 to a portion crossing the central portion HL1 of the first narrow passage EP1 to the other side of the first direction DR1. Accordingly, although the first light emitting element ED1 is not properly aligned in the display device manufacturing process, the contact between the second end ED1b of the first light emitting element ED1 and the second connection electrode CNE2 may be secured.

The third connection electrode CNE3 may at least partially overlap the second alignment electrode RME2 in the third direction DR3. The third connection electrode CNE3 may partially overlap one side of the second alignment electrode RME2 in the first direction DR1 to be in contact with the second end ED2b of the second light emitting element ED2.

As illustrated in FIG. 11, the third connection electrode CNE3 may extend in the first direction DR1 to a portion crossing the central portion HL2 of the second narrow passage EP2 to one side of the first direction DR1. Accordingly, although the second light emitting element ED2 is not properly aligned in the display device manufacturing process, the contact between the second end ED2b of the second light emitting element ED2 and the third connection electrode CNE3 may be secured.

The third connection electrode CNE3 may be in contact with the first connection electrode CNE1 in the outside of the emission area EMA through the node contact portion CTN penetrating the third insulating layer PAS3 as illustrated in FIG. 12. Accordingly, the first end ED1a of the first light emitting element ED1 may be electrically connected to the second end ED2b of the second light emitting element ED2, and the first light emitting element ED1 and the second light emitting element ED2 may be connected in series, so that the light efficiency of the sub-pixel SPXn may be improved.

The connection electrodes CNE may include a conductive material. For example, they may include ITO, IZO, ITZO, aluminum (Al), or the like. As an example, the connection electrodes CNE may include a transparent conductive material, and light emitted from the light emitting element ED may pass through the connection electrodes CNE to be emitted.

Each of the first insulating layer PAS1, the second insulating layer PAS2, and the third insulating layer PAS3 described above may include an inorganic insulating material or an organic insulating material. In an embodiment, each of the first insulating layer PAS1, the second insulating layer PAS2, and the third insulating layer PAS3 may include at least one of silicon oxide (SiOₓ), silicon nitride (SiNₓ), and silicon oxynitride (SiOₓN_{y}). The first insulating layer PAS1, the second insulating layer PAS2, and the third insulating layer PAS3 may be made of the same material or different materials. In another embodiment, some of them may be made of the same material and another of them may be made of different materials.

The low refractive area IRA may be formed at a portion where the second insulating layer PAS2 and the third insulating layer PAS3 expose a portion of the top surface of the external bank BNL near the edge of the emission area EMA, and a portion of the top surface of the first insulating layer PAS1 where the second connection electrode CNE2 and the third connection electrode CNE3 are spaced apart. The low refractive area IRA may be defined as an area in which, in a portion of the first insulating layer PAS1 on which the external bank BNL is not disposed, the second insulating layer PAS2, the first connection electrode layer CNEL1, the second connection electrode layer CNEL2, and the third insulating layer PAS3 are not disposed to expose the top surface of the first insulating layer PAS1, and as an area in which, on the external bank BNL, the second insulating layer PAS2, the first connection electrode layer CNEL1, the second connection electrode layer CNEL2, and the third insulating layer PAS3 are not disposed to expose the top surface of the external bank BNL.

The low refractive area IRA may provide a path through which light emitted from the light emitting element ED is not refracted to improve the luminous efficiency of each sub-pixel SPXn. Accordingly, as the area occupied by the low refractive area IRA increases, the luminous efficiency of the sub-pixel SPXn may be improved.

In the display device 1 according to one embodiment, the area of the low refractive area IRA may be increased, such that the luminous efficiency of the sub-pixel SPXn may be increased. For example, with reference to FIG. 11, the low refractive area IRA of the display device 1 according to one embodiment may also be disposed in the area between one side of the second connection electrode CNE2 in the first direction DR1 and the other side of the third connection electrode CNE3 in the first direction DR1, in addition to the area between the other side of the first connection electrode CNE1 in the first direction DR1 and the external bank BNL disposed on the other side of the first direction DR1 and the area between one side of the fourth connection electrode CNE4 in the first direction DR1 and the external bank BNL disposed on one side of the first direction DR1, so that the luminous efficiency of the sub-pixel SPXn may be further improved.

Hereinafter, a process of manufacturing the display device 1 according to one embodiment will be described.

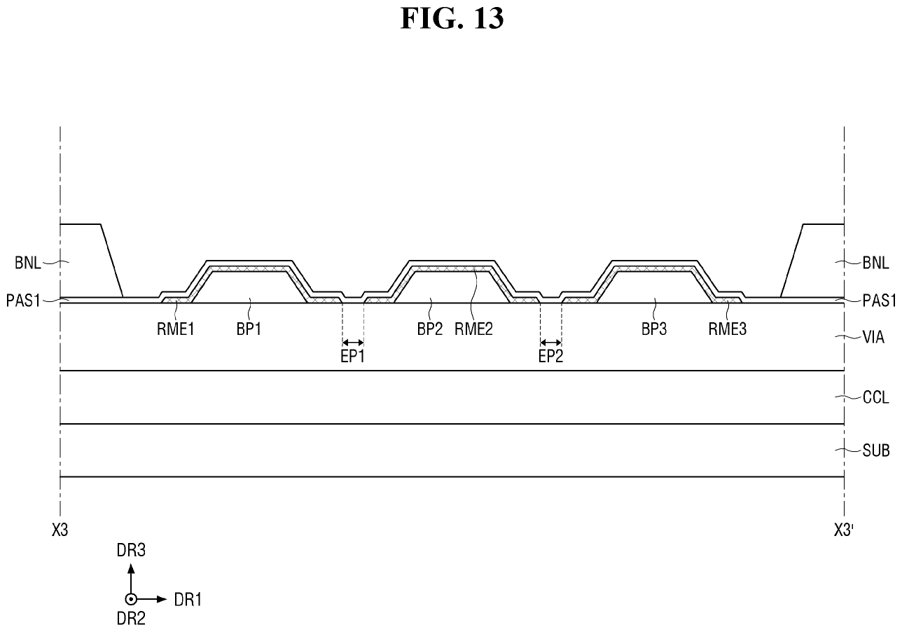

FIGS. 13 to 18 are schematic cross-sectional views showing the steps of a process of manufacturing a display device according to one embodiment.

FIGS. 13 to 18 illustrate process procedures of manufacturing the display device 1 according to one embodiment based on the cross-sectional view illustrated in FIG. 11.

Referring to FIG. 13, the circuit element layer CCL, the via insulating layer VIA, the alignment electrode RME, the first insulating layer PAS1, and the external bank BNL may be formed on the substrate SUB.

A description of the process of forming the circuit element layer CCL, the via insulating layer VIA, the alignment electrode RME, the first insulating layer PAS1 and the external bank BNL on the substrate SUB will be omitted.

The alignment electrodes RME may be spaced apart from each other in the first direction DR1 to form the narrow passages EP1 and EP2 that are spaces in which the light emitting elements ED are aligned. For example, the first narrow passage EP1 may be formed in a separation space between the first alignment electrode RME1 and the second alignment electrode RME2, and the second narrow passage EP2 may be formed in a separation space between the second alignment electrode RME2 and the third alignment electrode RME3.

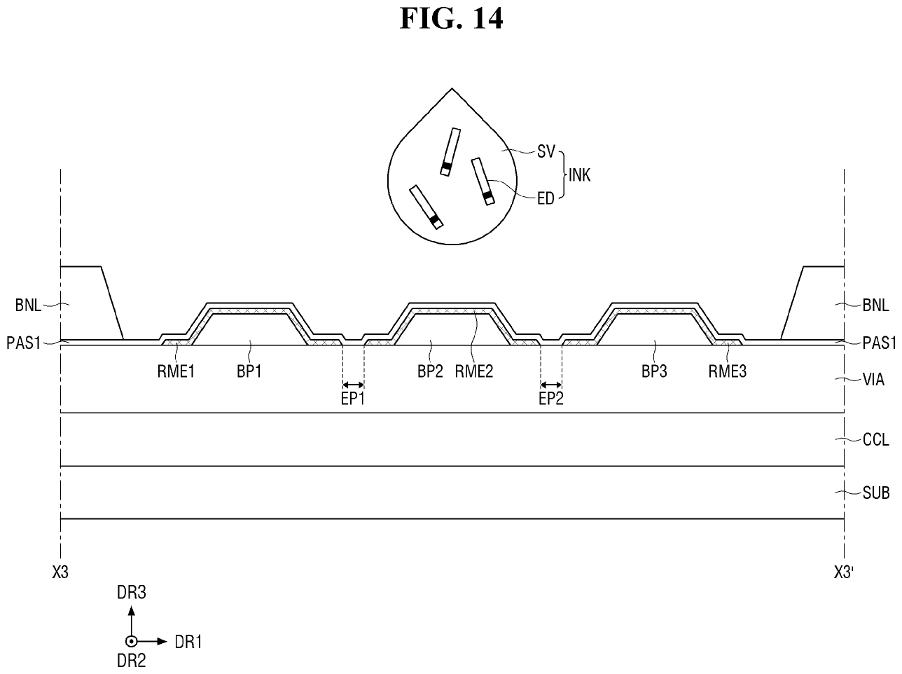

Referring to FIGS. 14 to 16, the light emitting element ED may be aligned with the alignment electrode RME. The process of aligning the light emitting elements ED may be performed using the dielectrophoresis (DEP) force caused by an electric field generated by alignment signals having different potential values.

An ink INK including a solvent SV and the light emitting element ED dispersed in the solvent SV may be ejected on the alignment electrode RME. The ejection of the ink INK may be performed by an inkjet printing apparatus. In case that the inkjet printing apparatus ejects the ink INK, the ink INK may be ejected to the area surrounded by the external bank BNL, for example, the emission area EMA (see FIG. 6).

The alignment signal may include the first alignment signal GND and the second alignment signal AC having a higher potential value than the first alignment signal GND. The first end of the light emitting element ED may be aligned in a direction to which the second alignment signal AC is applied, and the second end of the light emitting element ED may be aligned in a direction to which the first alignment signal GND is applied.

A first electric field IEL1 may be generated by applying the second alignment signal AC to the first alignment electrode RME1 and applying the first alignment signal GND to the second alignment electrode RME2. A second electric field IEL2 may be generated by applying the first alignment signal GND to the second alignment electrode RME2 and applying the second alignment signal AC to the third alignment electrode RME3. In some embodiments, the first electric field IEL1 and the second electric field IEL2 may be simultaneously generated, but the disclosure is not limited thereto. FIG. 15 illustrates that the first electric field IEL1 and the second electric field IEL2 are simultaneously generated.

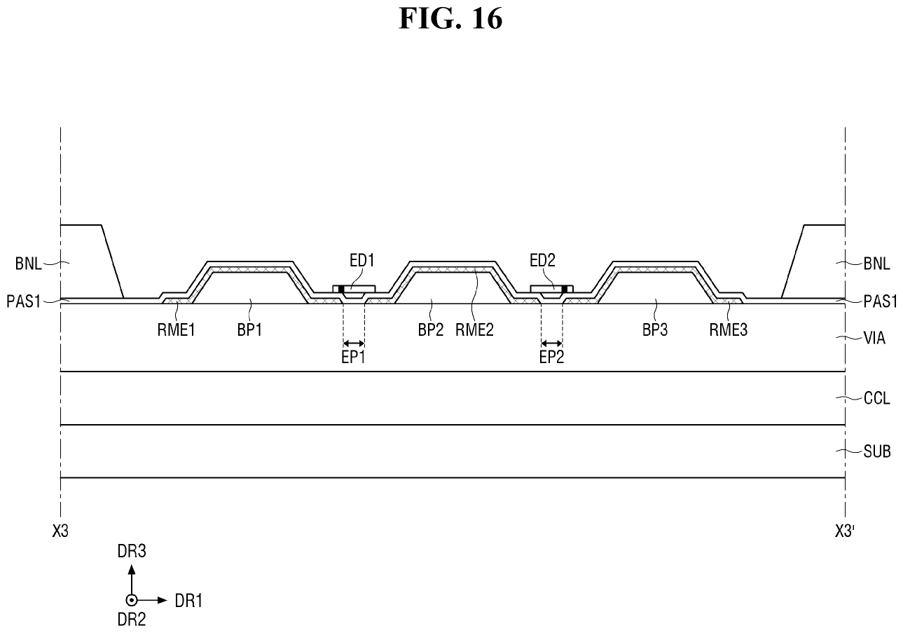

As the first electric field IEL1 and the second electric field IEL2 are formed, as illustrated in FIGS. 15 and 16, the first light emitting element ED1 may have a first end disposed on the first alignment electrode RME1 and a second end disposed on the second alignment electrode RME2 by the first electric field IEL1, and the second light emitting element ED2 may have a first end disposed on the third alignment electrode RME3 and a second end disposed on the second alignment electrode RME2 by the second electric field IEL2.

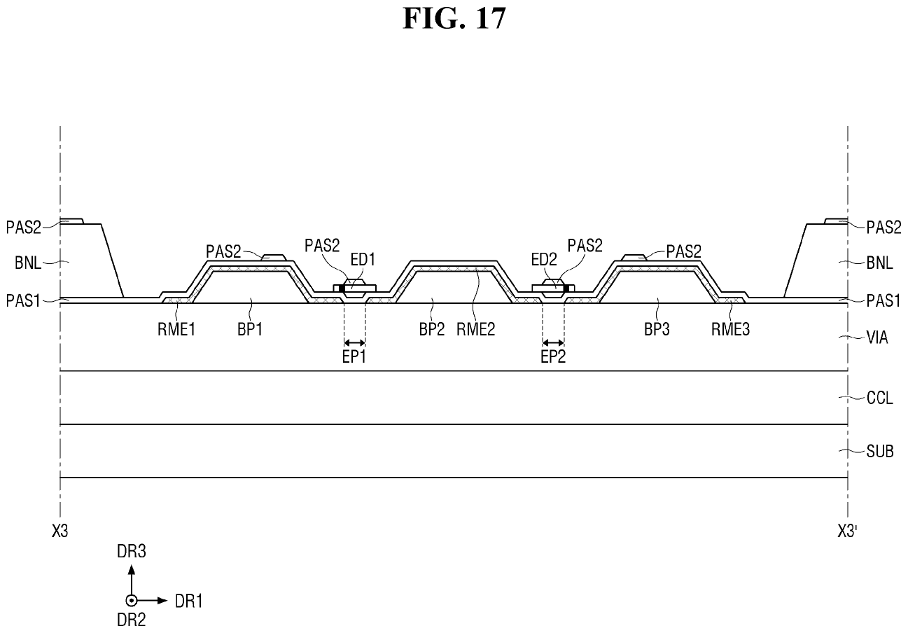

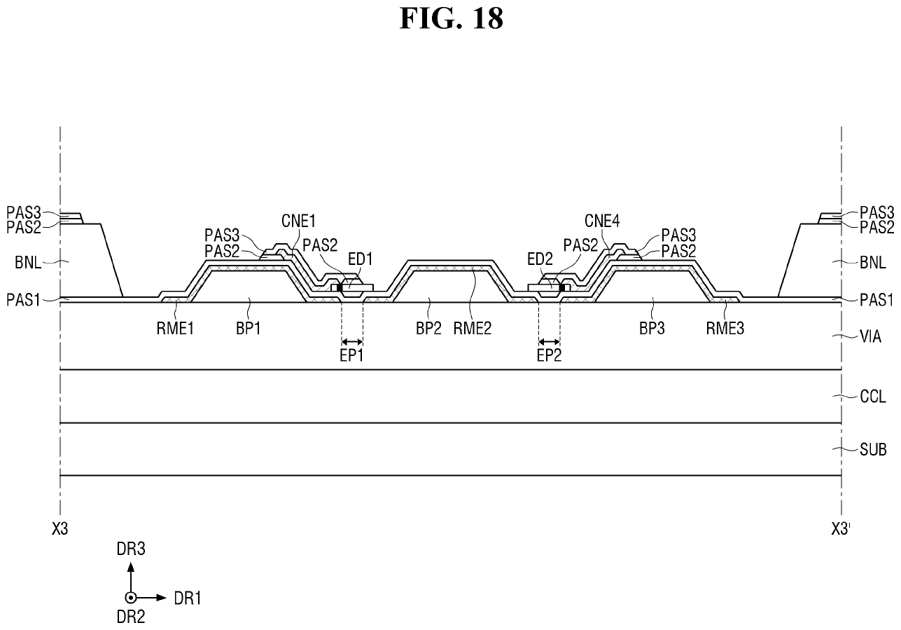

Referring to FIGS. 17 and 18, the second insulating layer PAS2, the first connection electrode CNE1, the fourth connection electrode CNE4, and the third insulating layer PAS3 may be sequentially stacked. The process of stacking the second insulating layer PAS2, the first connection electrode layer CNEL1, and the third insulating layer PAS3 may be performed by an etching process using a mask.

Each of the first connection electrode CNE1 and the fourth connection electrode CNE4 may be disposed between the second insulating layer PAS2 and the third insulating layer PAS3 and be completely covered by the second insulating layer PAS2 and the third insulating layer PAS3. Accordingly, the first connection electrode CNE1 may be electrically insulated from the second connection electrode CNE2 regardless of the width of the second connection electrode CNE2 to be disposed on the third insulating layer PAS3 in the first direction DR1, and the fourth connection electrode CNE4 may be electrically insulated from the third connection electrode CNE3 regardless of the width of the third connection electrode CNE3 to be disposed on the third insulating layer PAS3 in the first direction DR1.

The display device 1 illustrated in FIG. 11 may be manufactured by forming the second connection electrode CNE2 and the third connection electrode CNE3 on the third insulating layer PAS3.

In the alignment process of the light emitting element ED described in conjunction with FIGS. 14 to 16, an eccentricity phenomenon in which the first portion of the light emitting element ED is aligned biased toward a portion to which the second alignment signal AC is applied may occur. Hereinafter, as another example of the process of manufacturing the display device 1 according to one embodiment, a case in which the eccentricity phenomenon of the light emitting element ED occurs during the process of aligning the light emitting element ED will be described.

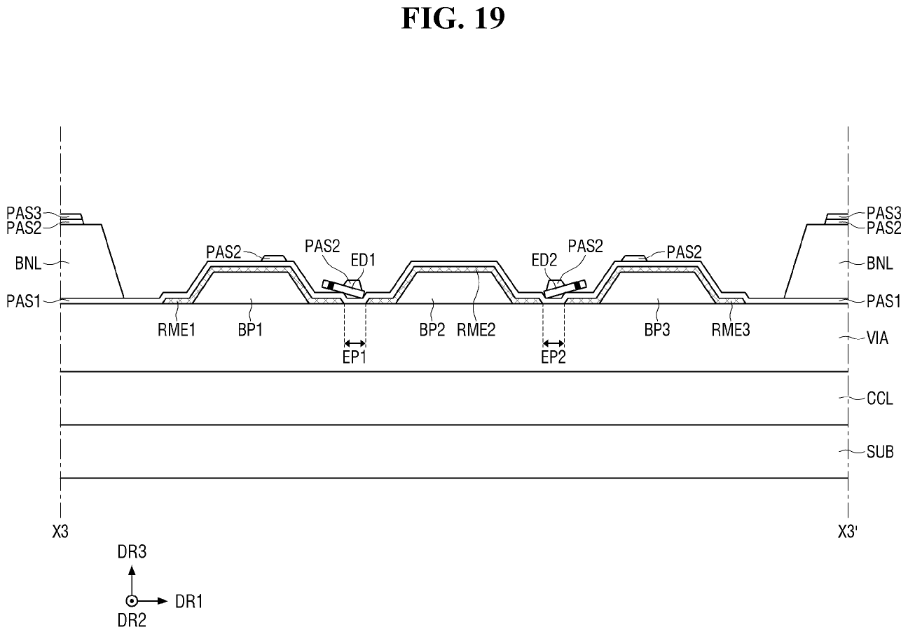

FIGS. 19 to 21 are schematic cross-sectional views showing the steps of another example of a process of manufacturing a display device according to one embodiment.

FIGS. 19 to 21 illustrate that the light emitting element ED is inclined (or tilted) and aligned due to the occurrence of the eccentricity phenomenon of the light emitting element ED during the process of aligning the light emitting element ED in the process of manufacturing the display device 1 according to one embodiment.

Referring to FIG. 19, during the alignment process of the light emitting element ED described above in conjunction with FIGS. 14 to 16, as the first end of the light emitting element ED is biased toward the alignment electrode RME applied with the second alignment signal AC (see FIG. 15), the second end thereof may be disposed to span a separation space between the alignment electrodes RME.

For example, the first end of the first light emitting element ED1 may be biased toward the other side of the first direction DR1 toward the first alignment electrode RME1 to which the second alignment signal AC is applied, and the second end thereof may be aligned to span a separation space between the first alignment electrode RME1 and the second alignment electrode RME2. In other words, the first light emitting element ED1 may be disposed to be inclined in the third direction DR3 with respect to a plane formed by the first direction DR1 and the second direction DR2.

In the same manner, the first end of the second light emitting element ED2 may be biased toward one side of the first direction DR1 toward the third alignment electrode RME3 to which the second alignment signal AC is applied, and the second end thereof may be aligned to span a separation space between the third alignment electrode RME3 and the second alignment electrode RME2. In other words, the second light emitting element ED2 may be disposed to be inclined (or tilted) in the third direction DR3 with respect to a plane formed by the first direction DR1 and the second direction DR2.

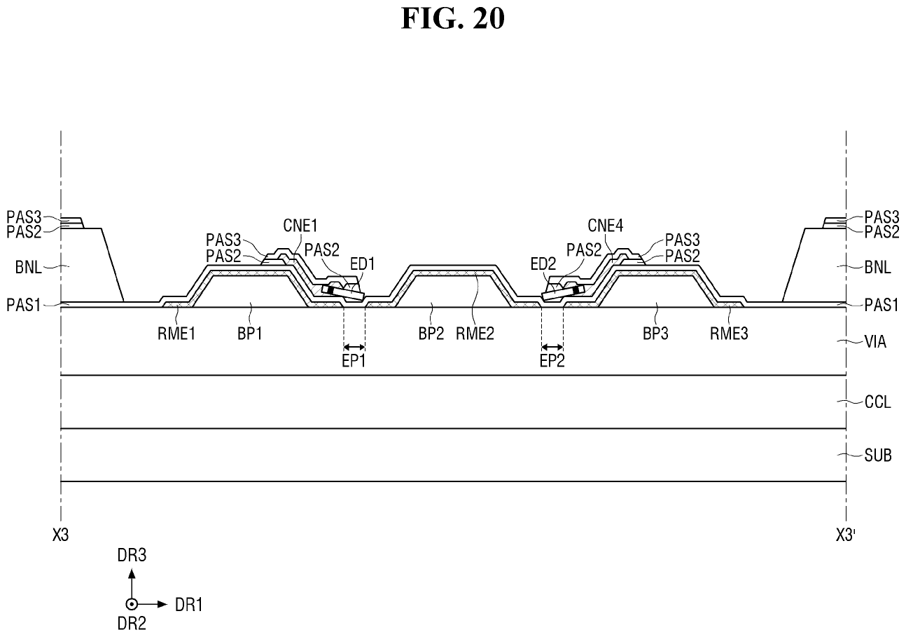

The second end of the first light emitting element ED1 may be not disposed on the second alignment electrode RME2, and the second end of the second light emitting element ED2 may be not disposed on the third alignment electrode RME3, so that as illustrated in FIG. 20, the area of the second end of the first light emitting element ED1 exposed by the second insulating layer PAS2 may be smaller than the area of the first end thereof exposed by the second insulating layer PAS2 to be in contact with the first connection electrode CNE1, and the area of the second end of the second light emitting element ED2 exposed by the second insulating layer PAS2 may be smaller than the area of the second end thereof exposed by the second insulating layer PAS2 to be in contact with the fourth connection electrode CNE4.

In case that the second end of the first light emitting element ED1 is not in contact with the second connection electrode CNE2 and the second end of the second light emitting element ED2 is not in contact with the third connection electrode CNE3, the first light emitting element ED1 and the second light emitting element ED2 may not emit light, so that the lighting efficiency of the pixel may decrease. Accordingly, it is necessary to ensure contact each of the second end of the first light emitting element ED1 and the second end of the second light emitting element ED2 that have relatively small areas by widening the widths of the second connection electrode CNE2 and the third connection electrode CNE3 in the first direction DR1.

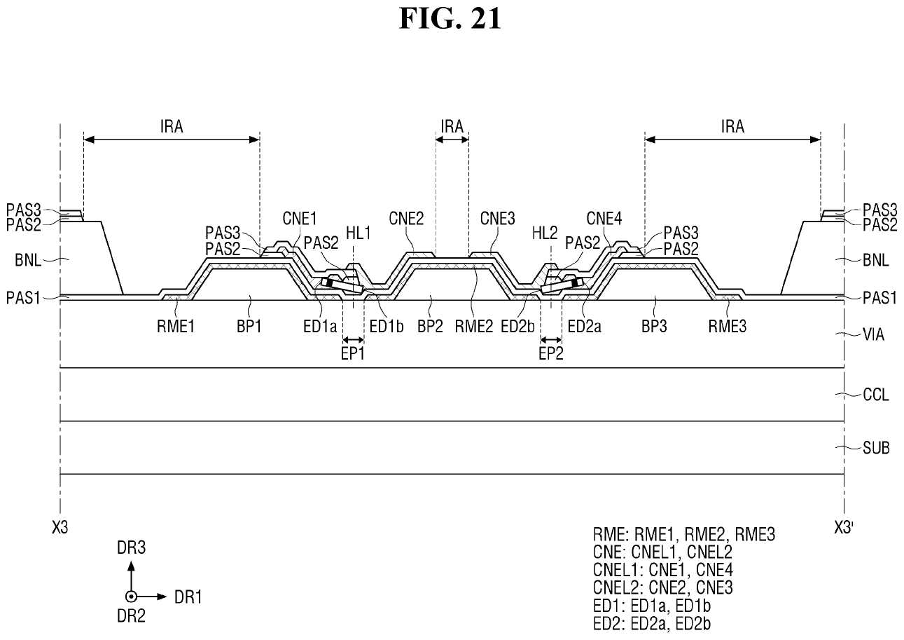

Referring to FIG. 21, the second connection electrode CNE2 may be extended beyond the other side of the central portion HL1 of the first narrow passage EP1 in the first direction DR1, and the third connection electrode CNE3 may be extended beyond one side of the central portion HL2 of the second narrow passage EP2 in the first direction DR1, so that contact between the second connection electrode CNE2 and the second end of the first light emitting element ED1 and contact between the third connection electrode CNE3 and the second end of the second light emitting element ED2 may be secured.

As described above in conjunction with FIG. 18, since each of the first connection electrode CNE1 and the fourth connection electrode CNE4 is surrounded by the second insulating layer PAS2 and the third insulating layer PASS, the width of each of the second connection electrode CNE2 and the third connection electrode CNE3 in the first direction DR1 may be freely extended. In other words, since the first connection electrode CNE1 and the second connection electrode CNE2 are electrically insulated regardless of the width of the second connection electrode CNE2 in the first direction DR1, contact between the second connection electrode CNE2 and the second end of the first light emitting element ED1 may be stably secured, and since the fourth connection electrode CNE4 and the third connection electrode CNE3 are electrically insulated regardless of the width of the third connection electrode CNE3 in the first direction DR1, contact between the third connection electrode CNE3 and the second end of the second light emitting element ED2 may be stably secured. Accordingly, the lighting efficiency of the pixel may be improved.

Hereinafter, other embodiments of the display device 1 will be described. In the following embodiments, description of the same components as those of the above-described embodiment, which are denoted by like reference numerals, will be omitted or simplified, and differences will be described.

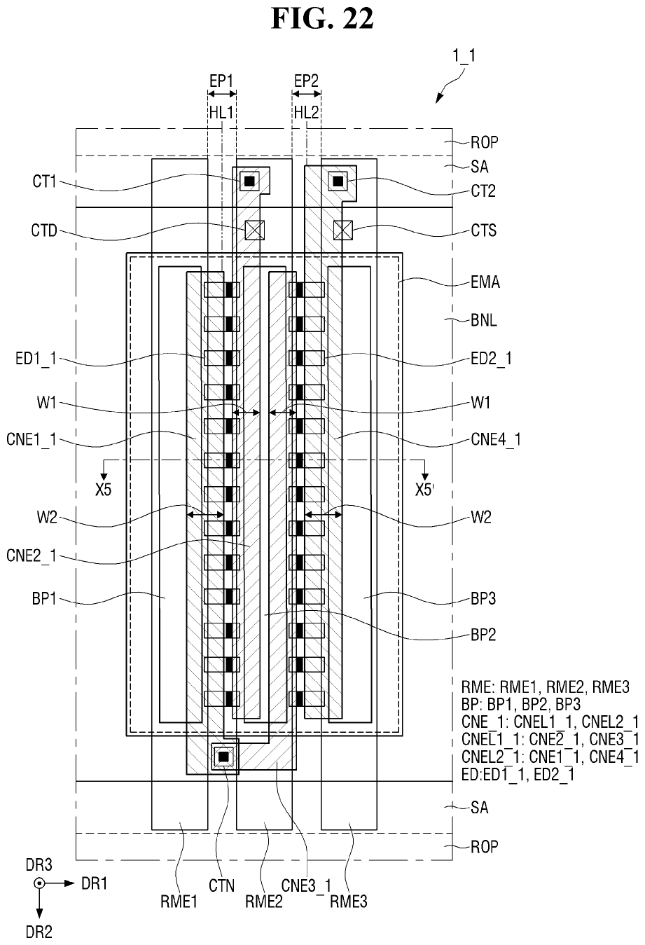

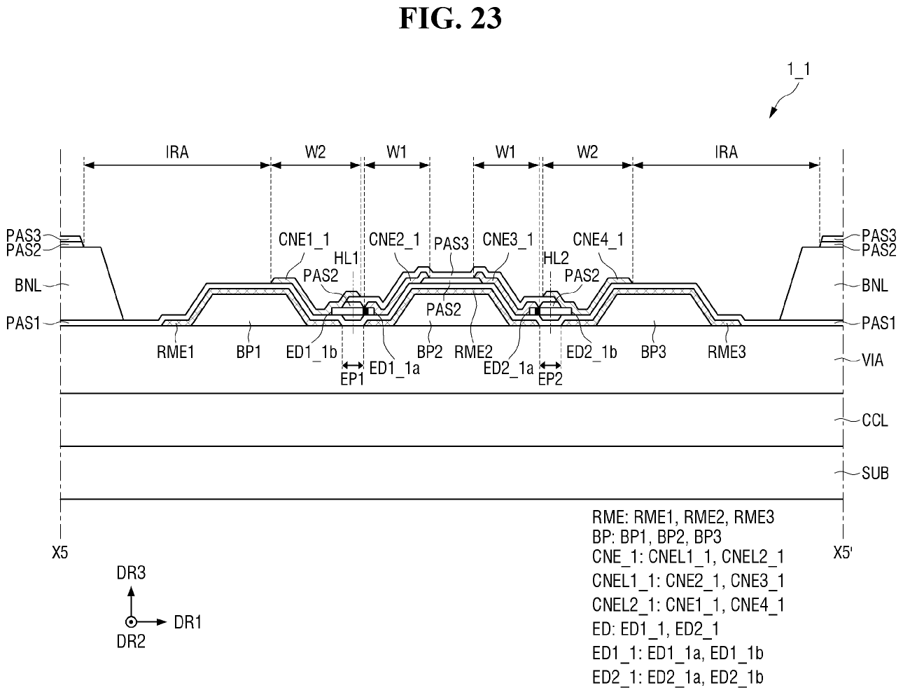

FIG. 22 is a plan view illustrating a pixel structure of a display device according to another embodiment. FIG. 23 is a schematic cross-sectional view of a pixel taken along line X5-X5′ of FIG. 22.

FIGS. 22 and 23 illustrates that the orientation of the light emitting element ED of a display device 1_1 according to the embodiment may be reversed compared to the display device 1 of FIG. 11. For example, the first end of a first light emitting element ED1_1 according to the embodiment may be disposed on the second alignment electrode RME2, the second end thereof may be disposed on the first alignment electrode RME1, the first end of a second light emitting element ED2_1 may be disposed on the second alignment electrode RME2, and the second end thereof may be disposed on the third alignment electrode RME3.

The second alignment electrode RME2 according to the embodiment may be electrically connected to the circuit element layer CCL through the first electrode contact hole CTD to be supplied with the first power voltage, and the third alignment electrode RME3 may be electrically connected to the circuit element layer CCL through the second electrode contact hole CTS to be supplied with the second power voltage.

A connection electrode CNE_1 of the display device 1_1 according to the embodiment may include a first connection electrode CNE1_1, a second connection electrode CNE2_1, a third connection electrode CNE3_1, and a fourth connection electrode CNE4_1 that are spaced apart from each other and sequentially arranged in the first direction DR1.

The first connection electrode CNE1_1, the second connection electrode CNE2_1, the third connection electrode CNE3_1, and the fourth connection electrode CNE4_1 may be spaced apart from each other and sequentially arranged in the first direction DR1. For example, the second connection electrode CNE2_1 may be disposed on one side of the first connection electrode CNE1_1 in the first direction DR1, the third connection electrode CNE3_1 may be disposed on one side of the second connection electrode CNE2_1 in the first direction DR1, and the fourth connection electrode CNE4_1 may be disposed on one side of the third connection electrode CNE3_1 in the first direction DR1.

The connection electrode CNE_1 may include a first connection electrode layer CNEL1_1 including the second connection electrode CNE2_1 and the third connection electrode CNE3_1, and a second connection electrode layer CNEL2_1 including the first connection electrode CNE1_1 and the fourth connection electrode CNE4_1. The first connection electrode layer CNEL1_1 and the second connection electrode layer CNEL2_1 may be distinguished according to a stacking order. For example, in the display device manufacturing process, the first connection electrode layer CNEL1_1 may be formed before the second connection electrode layer CNEL2_1.

For example, the second insulating layer PAS2 may be disposed under the first connection electrode layer CNEL1_1, and the third insulating layer PAS3 may be disposed between the first connection electrode layer CNEL1_1 and the second connection electrode layer CNEL2_1. In other words, the first connection electrode layer CNEL1_1 may be disposed on the second insulating layer PAS2, the third insulating layer PAS3 may be disposed on the first connection electrode layer CNEL1_1, and the second connection electrode layer CNEL2_1 may be disposed on the third insulating layer PAS3.

The first connection electrode layer CNEL1_1 and the second connection electrode layer CNEL2_1 of the display device 1_1 according to the embodiment may have opposite disposition relation with respect to the first connection electrode layer CNEL1 and the second connection electrode layer CNEL2 of FIG. 11. For example, two second connection electrode layers CNEL2_1 may be disposed to be spaced apart from each other in one sub-pixel of the display device 1_1, and two first connection electrode layers CNEL1_1 may be disposed to be spaced apart from each other in a separation space between the two second connection electrode layers CNEL2_1.

The first connection electrode layer CNEL1_1 disposed on the second insulating layer PAS2 may have the first width W1 in the first direction DR1. The first connection electrode layer CNEL1_1 may include the connection electrodes CNE_1 in contact with the first end of the light emitting element ED. For example, in the emission area EMA, each of the second connection electrode CNE2_1 and the third connection electrode CNE3_1 may have the first width W1 in the first direction DR1.

In some embodiments, each of the second connection electrode CNE2_1 and the third connection electrode CNE3_1 may have the same width, but is not limited thereto. For example, the second connection electrode CNE2_1 and the third connection electrode CNE3_1 may have different widths. FIG. 22 illustrates that the second connection electrode CNE2_1 and the third connection electrode CNE3_1 have the same first width W1.

The second connection electrode CNE2_1 of the first connection electrode layer CNEL1_1 may be disposed on the other side of the second alignment electrode RME2 in the first direction DR1. The second connection electrode CNE2_1 may generally have the first width W1 in the first direction DR1 and may have a shape extending in the second direction DR2. The second connection electrode CNE2_1 may partially overlap the first narrow passage EP1 in the emission area EMA in a plan view, but may not overlap the central portion HL1 of the first narrow passage EP1 in a plan view.

A portion of the second connection electrode CNE2_1 may be connected to the second alignment electrode RME2 through the first contact portion CT1 penetrating the second insulating layer PAS2 as illustrated in FIGS. 22 and 23 in an area that does not overlap the emission area EMA. Accordingly, the second connection electrode CNE2_1 may be supplied with the above-described first power voltage through the second alignment electrode RME2.

Another portion of the second connection electrode CNE2_1 may be in contact with a first end ED1_1a of the first light emitting element ED1_1 in the emission area EMA. For example, the another portion of the second connection electrode CNE2_1 may extend in the second direction DR2 in the emission area EMA, and may be in contact with the first ends ED1_1a of the first light emitting elements ED1_1 arranged in the second direction DR2 in the first narrow passage EP1.

As illustrated in FIG. 23, the patterned second insulating layer PAS2 on the internal bank BP2 may be disposed under one side of the second connection electrode CNE2_1 in the first direction DR1. The second insulating layer PAS2 pattern disposed under one side of the second connection electrode CNE2_1 in the first direction DR1 may effectively cover one side surface of the second connection electrode CNE2_1 in the first direction DR1 together with the third insulating layer PAS3.

The third connection electrode CNE3_1 of the first connection electrode layer CNEL1_1 may be disposed on one side of the second alignment electrode RME2 in the first direction DR1 in the emission area EMA. The third connection electrode CNE3_1 may generally have the first width W1 in the first direction DR1 in the emission area EMA and may have a shape extending in the second direction DR2. The third connection electrode CNE3_1 may partially overlap the second narrow passage EP2 in the emission area EMA in a plan view, but may not overlap the central portion HL2 of the second narrow passage EP2 in a plan view.

In some embodiments, the third connection electrode CNE3_1 may have a shape that is bent at least once at a portion that does not overlap the emission area EMA, but is not limited thereto. FIG. 22 illustrates that the third connection electrode CNE3_1 extends in the emission area EMA in the second direction DR2 and has a shape bent in the first direction DR1 on the external bank BNL disposed on one side of the emission area EMA in the second direction DR2.

The third connection electrode CNE3_1 may be in contact with a first end ED2_1a of the second light emitting element ED2_1 in the emission area EMA. For example, the third connection electrode CNE3_1 may have the first width W1 in the first direction DR1 in the emission area EMA and extend in the second direction DR2, and may be in contact with the first ends ED2_1a of the second light emitting elements ED2_1 arranged in the second direction DR2 in the second narrow passage EP2.

The third connection electrode CNE3_1 may be bent to the other side of the first direction DR1 on the external bank BNL disposed on one side of the emission area EMA in the second direction DR2 to be electrically connected to the first connection electrode CNE1_1 to be described later.

As illustrated in FIG. 23, the patterned second insulating layer PAS2 on the internal bank BP2 may be disposed under the other side of the third connection electrode CNE3_1 in the first direction DR1. The second insulating layer PAS2 pattern disposed under the other side of the third connection electrode CNE3_1 in the first direction DR1 may effectively cover the other side surface of the third connection electrode CNE3_1 in the first direction DR1 together with the third insulating layer PAS3.

The second connection electrode layer CNEL2_1 disposed on the third insulating layer PAS3 may have the second width W2 in the first direction DR1. The second connection electrode layer CNEL2_1 may include the connection electrodes CNE in contact with the second end of the light emitting element ED. For example, in the emission area EMA, each of the first connection electrode CNE1_1 and the fourth connection electrode CNE4_1 may have the second width W2 in the first direction DR1. Accordingly, the second connection electrode layer CNEL2_1 may secure contact with the second end of the light emitting element ED although the light emitting element ED is not properly aligned in a display device manufacturing process.

In some embodiments, each of the first connection electrode CNE1_1 and the fourth connection electrode CNE4_1 may have the same width, but is not limited thereto. For example, the first connection electrode CNE1_1 and the fourth connection electrode CNE4_1 may have different widths. FIG. 22 illustrates that the first connection electrode CNE1_1 and the fourth connection electrode CNE4_1 have the same second width W2.

The first connection electrode CNE1_1 of the second connection electrode layer CNEL2_1 may be disposed on the first alignment electrode RME1 in the emission area EMA. The second connection electrode layer CNEL2_1 may generally have the second width W2 in the first direction DR1 in the emission area EMA and may have a shape extending in the second direction DR2.

In some embodiments, the first connection electrode CNE1_1 may have a shape that is bent at least once at a portion that does not overlap the emission area EMA in a plan view, but is not limited thereto. FIG. 22 illustrates that the first connection electrode CNE1_1 extends in the second direction DR2 in the emission area EMA and has a shape bent in the first direction DR1 on the external bank BNL disposed on one side of the emission area EMA in the second direction DR2.

The first connection electrode CNE1_1 may be in contact with a second end ED1_1b of the first light emitting element ED1_1 in the emission area EMA. For example, the first connection electrode CNE1_1 may have the second width W2 in the first direction DR1 in the emission area EMA and extend in the second direction DR2, and may be in contact with the second ends ED1_1b of the first light emitting elements ED1_1 arranged in the second direction DR2.

The first connection electrode CNE1_1 may be bent to one side of the first direction DR1 on the external bank BNL disposed on one side of the emission area EMA in the second direction DR2 to be electrically connected to the third connection electrode CNE3_1 through the node contact portion CTN penetrating the third insulating layer PAS3 as illustrated in FIG. 23.

The first connection electrode CNE1_1 may partially overlap the first narrow passage EP1 in the emission area EMA to cover the central portion HL1 of the first narrow passage EP1 in a plan view. For example, in the first narrow passage EP1, the first connection electrode CNE1_1 may reach a point beyond the central portion HL1 of the first narrow passage EP1 to completely cover the central portion HL1 of the first narrow passage EP1. In other words, as illustrated in FIG. 23, the first connection electrode CNE1_1 may extend in the first direction DR1 to a portion crossing the central portion HL1 of the first narrow passage EP1 to one side of the first direction DR1. Accordingly, although the first light emitting element ED1_1 is not properly aligned in the display device manufacturing process, the contact between the second end ED1_1b of the first light emitting element ED1_1 and the first connection electrode CNE1_1 may be secured.

Accordingly, contact between the third connection electrode CNE3_1 and the second end of the second light emitting element ED2_1 may be secured although the second light emitting element ED2_1 is not properly aligned in a display device manufacturing process to be described later.

The fourth connection electrode CNE4_1 of the second connection electrode layer CNEL2_1 may be disposed on the third alignment electrode RME3. The fourth connection electrode CNE4_1 may generally have the second width W2 in the first direction DR1 and may have a shape extending in the second direction DR2.

A portion of the fourth connection electrode CNE4_1 may be connected to the third alignment electrode RME3 through the second contact portion CT2 penetrating the second insulating layer PAS2 and the third insulating layer PAS3 in an area that does not overlap the emission area EMA. Accordingly, the fourth connection electrode CNE4_1 may be supplied with the above-described second power voltage through the third alignment electrode RME3.

Another portion of the fourth connection electrode CNE4_1 may be in contact with a second end ED2_1b of the second light emitting element ED2_1 in the emission area EMA. For example, the another portion of the fourth connection electrode CNE4_1 may extend in the second direction DR2 in the emission area EMA, and may be in contact with the second ends ED2_1b of the second light emitting elements ED2_1 arranged in the second direction DR2 in the second narrow passage EP2.

The fourth connection electrode CNE4_1 may partially overlap the second narrow passage EP2 in the emission area EMA to cover the central portion HL2 of the second narrow passage EP2. For example, in the second narrow passage EP2, the fourth connection electrode CNE4_1 may reach a point beyond the central portion HL2 of the second narrow passage EP2 to completely cover the central portion HL2 of the second narrow passage EP2 in a plan view. In other words, as illustrated in FIG. 23, the fourth connection electrode CNE4_1 may extend in the first direction DR1 to a portion crossing the central portion HL2 of the second narrow passage EP2 to one side of the first direction DR1. Accordingly, although the second light emitting element ED2_1 is not properly aligned in the display device manufacturing process, the contact between the second end ED2_1b of the second light emitting element ED2_1 and the fourth connection electrode CNE4_1 may be secured.

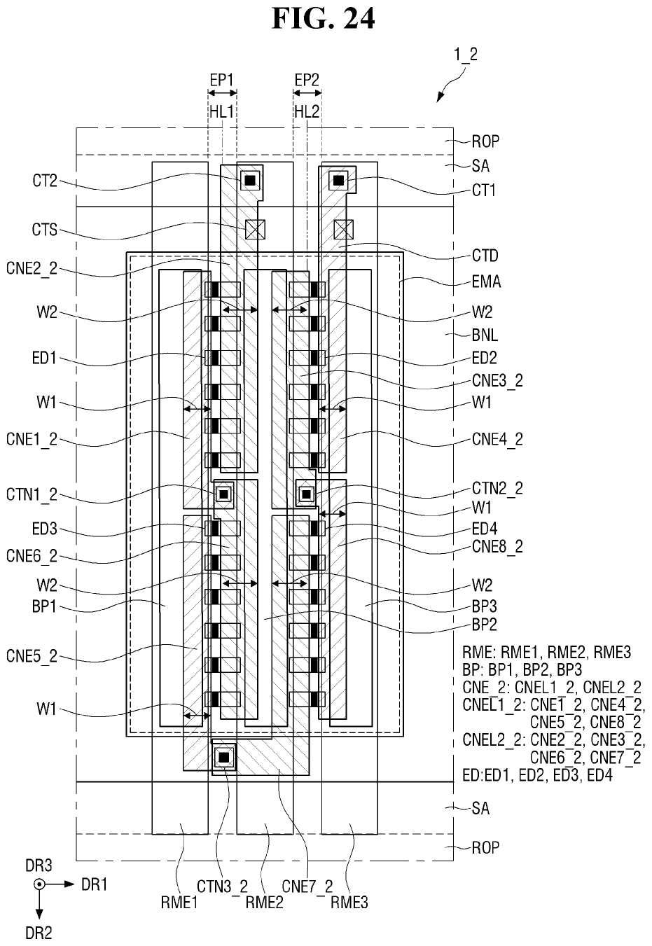

FIG. 24 is a plan view illustrating a pixel structure of a display device according to yet another embodiment.

FIG. 24 illustrates that the number of the connection electrodes CNE_2 of a display device 1_2 may be added and the number of node contact portions CTN1_2, CTN2_2, and CTN3_2 that are electrically connected with the first connection electrode layer CNEL1_2 and the second connection electrode layer CNEL2_2 may be increased. The display device 1_2 according to the embodiment may have four light emitting elements ED (ED1, ED2, ED3, and ED4) connected in series.

The light emitting element ED according to the embodiment may include a third light emitting element ED3 and a fourth light emitting element ED4 as well as the first light emitting element ED1 and the second light emitting element ED2.

Multiple third light emitting elements ED3 may be disposed on the first narrow passage EP1 that is a separation space between the first alignment electrode RME1 and the second alignment electrode RME2, and may be arranged in the second direction DR2. The group formed by the third light emitting elements ED3 may be disposed to be spaced apart from the group formed by the first light emitting elements ED1 in one side of the second direction DR2.

The orientation of the third light emitting element ED3 may be the same as the orientation of the first light emitting element ED 1. For example, a first end of the third light emitting element ED3 may be disposed on the first alignment electrode RME1, and a second end thereof may be disposed on the second alignment electrode RME2.

Multiple fourth light emitting elements ED4 may be disposed on the second narrow passage EP2 that is a separation space between the second alignment electrode RME2 and the third alignment electrode RME3 and may be arranged in the second direction DR2. The group formed by the fourth light emitting elements ED4 may be disposed to be spaced apart from the group formed by the second light emitting elements ED2 in one side of the second direction DR2.

The orientation of the fourth light emitting element ED4 may be the same as the orientation of the second light emitting element ED2. For example, a first end of the fourth light emitting element ED4 may be disposed on the third alignment electrode RME3, and a second end thereof may be disposed on the second alignment electrode RME2.

The connection electrodes CNE_2 according to the embodiment may include, as a first group, a first connection electrode CNE1_2, a second connection electrode CNE2_2, a third connection electrode CNE3_2, and a fourth connection electrode CNE4_2 that are spaced apart from each other and are sequentially arranged in the first direction DR1, and may include, as a second group that is spaced apart from the first group in the second direction DR2 and arranged on one side of the first direction DR1, a fifth connection electrode CNE5_2, a sixth connection electrode CNE6_2, a seventh connection electrode CNE7_2, and an eighth connection electrode CNE8_2.

In some embodiments, the first connection electrode CNE1_2 and the fifth connection electrode CNE5_2 may be arranged in the second direction DR2, the second connection electrode CNE2_2 and the sixth connection electrode CNE6_2 may be arranged in the second direction DR2, the third connection electrode CNE3_2 and the seventh connection electrode CNE7_2 may be arranged in the second direction DR2, and the fourth connection electrode CNE4_2 and the eighth connection electrode CNE8_2 may be arranged in the second direction DR2, but the disclosure is not limited thereto. FIG. 24 illustrates that the first connection electrode CNE1_2 and the fifth connection electrode CNE5_2 are arranged in the second direction DR2, the second connection electrode CNE2_2 and the sixth connection electrode CNE6_2 are arranged in the second direction DR2, the third connection electrode CNE3_2 and the seventh connection electrode CNE7_2 are arranged in the second direction DR2, and the fourth connection electrode CNE4_2 and the eighth connection electrode CNE8_2 are arranged in the second direction DR2.

The connection electrode CNE_2 may include a first connection electrode layer CNEL1_2 including the first connection electrode CNE1_2, the fourth connection electrode CNE4_2, the fifth connection electrode CNE5_2, and the eighth connection electrode CNE8_2, and a second connection electrode layer CNEL2_2 including the second connection electrode CNE2_2, the third connection electrode CNE3_2, the sixth connection electrode CNE6_2, and the seventh connection electrode CNE7_2.

The stacking relationship and disposition relationship of the first connection electrode layer CNEL1_2 and the second connection electrode layer CNEL2_2 are substantially the same as those of the first connection electrode layer CNEL1 and the second connection electrode layer CNEL2 of FIG. 11, so that a detailed description thereof will be omitted.

The first connection electrode CNE1_2 may be disposed on the first alignment electrode RME1. The first connection electrode CNE1_2 may generally have the first width W1 in the first direction DR1, extend in the second direction DR2, and have a shape that is bent at least once in the first direction DR1 near the center of the emission area EMA.

A portion of the first connection electrode CNE1_2 extending in the second direction DR2 may be in contact with the first end of the first light emitting element ED1, and a portion thereof bent in the first direction DR1 may be electrically connected to the sixth connection electrode CNE6_2 through a first node contact portion CTN1_2. The portion of the first connection electrode CNE1_2 bent in the first direction DR1 may cross a separation space between the first light emitting element ED1 and the third light emitting element ED3 in the second direction DR2.

The second connection electrode CNE2_2 may be disposed on the other side of the second alignment electrode RME2 in the first direction DR1. The second connection electrode CNE2 may generally have the second width W2 in the first direction DR1 and may have a shape extending in the second direction DR2 to the vicinity of the center of the emission area EMA. The second connection electrode CNE2_2 may be in contact with the second end of the first light emitting element ED1.

The second connection electrode CNE2_2 may partially overlap the first narrow passage EP1 in the emission area EMA to cover the central portion HL1 of the first narrow passage EP1 in a plan view. For example, in the first narrow passage EP1, the second connection electrode CNE2_2 may reach a point beyond the central portion HL1 of the first narrow passage EP1 to completely cover the central portion HL1 of the first narrow passage EP1. Accordingly, contact between the second connection electrode CNE2_2 and the second end of the first light emitting element ED1 may be secured although the first light emitting element ED1 is not properly aligned in the display device manufacturing process.

Other description of the second connection electrode CNE2_2 will be omitted since it is substantially the same as the description of the second connection electrode CNE2 of FIG. 11.

The third connection electrode CNE3_2 may be disposed on one side of the second alignment electrode RME2 in the first direction DR1. The third connection electrode CNE3_2 may generally have the second width W2 in the first direction DR1, extend in the second direction DR2, and have a shape that is bent at least once in the first direction DR1 near the center of the emission area EMA.

A portion of the third connection electrode CNE3_2 extending in the second direction DR2 may be in contact with the second end of the second light emitting element ED2, and a portion thereof bent in the first direction DR1 may be electrically connected to the eighth connection electrode CNE8_2 through the second node contact portion CTN2_2. The portion of the third connection electrode CNE3_2 bent in the first direction DR1 may cross a separation space between the second light emitting element ED2 and the fourth light emitting element ED4 in the second direction DR2.

The third connection electrode CNE3_2 may partially overlap the second narrow passage EP2 in the emission area EMA to cover the central portion HL2 of the second narrow passage EP2 in a plan view. For example, in the second narrow passage EP2, the third connection electrode CNE3_2 may reach a point beyond the central portion HL2 of the second narrow passage EP2 to completely cover the central portion HL2 of the second narrow passage EP2. Accordingly, contact between the third connection electrode CNE3_2 and the second end of the second light emitting element ED2 may be secured although the second light emitting element ED2 is not properly aligned in the display device manufacturing process.

The fourth connection electrode CNE4_2 may be disposed on the third alignment electrode RME3. The fourth connection electrode CNE4_2 may generally have the first width W1 in the first direction DR1 and may have a shape extending in the second direction DR2 to the vicinity of the center of the emission area EMA. The fourth connection electrode CNE4_2 may be in contact with the first end of the second light emitting element ED2.

Other description of the fourth connection electrode CNE4_2 will be omitted since it is substantially the same as the description of the fourth connection electrode CNE4 of FIG. 11.

The fifth connection electrode CNE5_2 may be disposed on the first alignment electrode RME1 to be spaced apart from the first connection electrode CNE1_2 in the second direction DR2. The fifth connection electrode CNE5_2 may generally have the first width W1 in the first direction DR1, extend in the second direction DR2 from the vicinity of the center of the emission area EMA, and have a shape that is bent at least once in the first direction DR1 on the external bank BNL disposed on one side of the emission area EMA in the second direction DR2.

A portion of the fifth connection electrode CNE5_2 extending in the second direction DR2 may be in contact with the first end of the third light emitting element ED3, and a portion thereof bent in the first direction DR1 may be electrically connected to the seventh connection electrode CNE7_2 through the third node contact portion CTN3_2. The portion of the fifth connection electrode CNE5_2 bent in the first direction DR1 may be disposed outside the emission area EMA.

The sixth connection electrode CNE6_2 may be disposed on the other side of the second alignment electrode RME2 in the first direction DR1 to be spaced apart from the second connection electrode CNE2_2 in the second direction DR2. The sixth connection electrode CNE6_2 may generally have the second width W2 in the first direction DR1 and may have a shape extending in the second direction DR2 from the vicinity of the center of the emission area EMA. The sixth connection electrode CNE6_2 may be in contact with the second end of the third light emitting element ED3.

The sixth connection electrode CNE6_2 may partially overlap the first narrow passage EP1 in the emission area EMA to cover the central portion HL1 of the first narrow passage EP1 in a plan view. For example, in the first narrow passage EP1, the sixth connection electrode CNE6_2 may reach a point beyond the central portion HL1 of the first narrow passage EP1 to completely cover the central portion HL1 of the first narrow passage EP1. Accordingly, contact between the sixth connection electrode CNE6_2 and the second end of the third light emitting element ED3 may be secured although the third light emitting element ED3 is not properly aligned in the display device manufacturing process.

The seventh connection electrode CNE7_2 may be disposed on one side of the second alignment electrode RME2 in the first direction DR1 to be spaced apart from the third connection electrode CNE3_2 in the second direction DR2. The seventh connection electrode CNE7_2 may generally have the second width W2 in the first direction DR1, extend in the second direction DR2 from the vicinity of the center of the emission area EMA, and have a shape that is bent at least once in the first direction DR1 on the external bank BNL disposed on one side of the emission area EMA in the second direction DR2.

A portion of the seventh connection electrode CNE7_2 extending in the second direction DR2 may be in contact with the second end of the fourth light emitting element ED4 in the emission area EMA. A portion of the seventh connection electrode CNE7_2 bent in the first direction DR1 may be electrically connected to the sixth connection electrode CNE6_2 through the third node contact portion CTN3_2.

The seventh connection electrode CNE7_2 may partially overlap the second narrow passage EP2 in the emission area EMA to cover the central portion HL2 of the second narrow passage EP2 in a plan view. For example, in the second narrow passage EP2, the seventh connection electrode CNE7_2 may reach a point beyond the central portion HL2 of the second narrow passage EP2 to completely cover the central portion HL2 of the second narrow passage EP2. Accordingly, although the fourth light emitting element ED4 is not properly aligned in the display device manufacturing process, contact between the seventh connection electrode CNE7_2 and the second end of the fourth light emitting element ED4 may be secured.

The eighth connection electrode CNE8_2 may be disposed on the third alignment electrode RME3 to be spaced apart from the fourth connection electrode CNE4_2 in the second direction DR2. The eighth connection electrode CNE8_2 may generally have the first width W1 in the first direction DR1, be bent in the first direction DR1 near the center of the emission area EMA, and have a shape extending in the second direction DR2 in the emission area EMA. A portion of the eighth connection electrode CNE8_2 extending in the second direction DR2 may be in contact with the first end of the fourth light emitting element ED4, and a portion thereof bent in the first direction DR1 may be electrically connected to the third connection electrode CNE3_2 through the second node contact portion CTN2_2.

The structure in which the first connection electrode layer CNEL1_2 and the second connection electrode layer CNEL2_2 are in contact with each other in the first node contact portion CTN1_2, the second node contact portion CTN2_2, and the third node contact portion CTN3_2 is substantially the same as the structure described above in FIG. 11, and thus a detailed description thereof will be omitted.

According to the configuration as described above, in the display device 1_2 according to the embodiment, four different light emitting elements ED may be connected in series to improve the luminous efficiency of the pixel, and the contact of the second end of each of the light emitting elements ED may be stably secured.

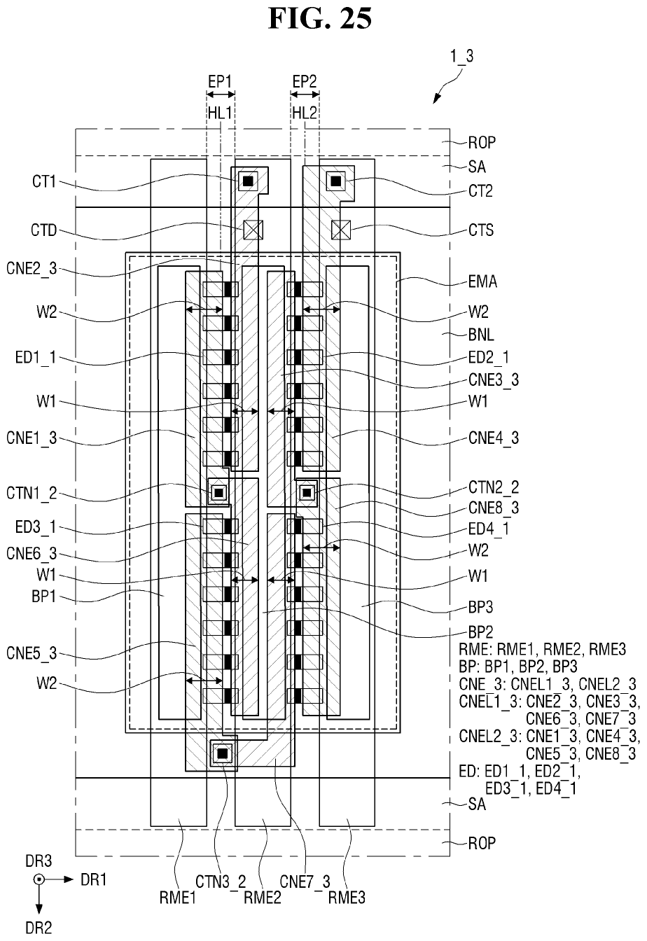

FIG. 25 is a plan view illustrating a pixel structure of a display device according to yet another embodiment.

Referring to FIG. 25, in a display device 1_3 according to the embodiment, as compared to the display device 1_2 according to the embodiment of FIG. 24, there is a difference in that the orientation of the light emitting element ED is reversed and the first connection electrode layer CNEL1_3 and the second connection electrode layer CNEL2_3 of the connection electrode CNE_3 have opposite disposition, and other configurations are substantially the same or similar.

The light emitting element ED according to the embodiment may include a third light emitting element ED3_1 and a fourth light emitting element ED4_1 as well as the first light emitting element ED1_1 and the second light emitting element ED2_1.

Multiple third light emitting elements ED3_1 may be disposed on the first narrow passage EP1 that is a separation space between the first alignment electrode RME1 and the second alignment electrode RME2, and may be arranged in the second direction DR2. The group formed by the third light emitting elements ED3_1 may be disposed to be spaced apart from the group formed by the first light emitting elements ED1_1 in the second direction DR2.

The orientation of the third light emitting element ED3_1 may be the same as the orientation of the first light emitting element ED1_1. For example, the first end of the third light emitting element ED3 may be disposed on the second alignment electrode RME2, and the second end thereof may be disposed on the first alignment electrode RME1.

Multiple fourth light emitting elements ED4_1 may be disposed on the second narrow passage EP2 that is a separation space between the second alignment electrode RME2 and the third alignment electrode RME3 and may be arranged in the second direction DR2. The group formed by the fourth light emitting elements ED4_1 may be disposed to be spaced apart from the group formed by the second light emitting elements ED2_1 in the second direction DR2.

The orientation of the fourth light emitting element ED4_1 may be the same as the orientation of the second light emitting element ED2_1. For example, the first end of the fourth light emitting element ED4_1 may be disposed on the second alignment electrode RME2, and the second end thereof may be disposed on the third alignment electrode RME3.

The connection electrodes CNE_3 according to the embodiment may include, as a first group, a first connection electrode CNE1_3, a second connection electrode CNE2_3, a third connection electrode CNE3_3, and a fourth connection electrode CNE4_3 that are spaced apart from each other and are sequentially arranged in the first direction DR1, and may include, as a second group that is spaced apart from the first group in the second direction DR2 and arranged in the first direction DR1, a fifth connection electrode CNE5_3, a sixth connection electrode CNE6_3, a seventh connection electrode CNE7_3, and an eighth connection electrode CNE8_3.

In some embodiments, the first connection electrode CNE1_3 and the fifth connection electrode CNE5_3 may be arranged in the second direction DR2, the second connection electrode CNE2_3 and the sixth connection electrode CNE6_3 may be arranged in the second direction DR2, the third connection electrode CNE3_3 and the seventh connection electrode CNE7_3 may be arranged in the second direction DR2, and the fourth connection electrode CNE4_3 and the eighth connection electrode CNE8_3 may be arranged in the second direction DR2, but the disclosure is not limited thereto. FIG. 24 illustrates that the first connection electrode CNE1_3 and the fifth connection electrode CNE5_3 are arranged in the second direction DR2, the second connection electrode CNE2_3 and the sixth connection electrode CNE6_3 are arranged in the second direction DR2, the third connection electrode CNE3_3 and the seventh connection electrode CNE7_3 are arranged in the second direction DR2, and the fourth connection electrode CNE4_3 and the eighth connection electrode CNE8_3 are arranged in the second direction DR2.

The connection electrode CNE_3 may include the first connection electrode layer CNEL1_3 including the first connection electrode CNE1_3, the fourth connection electrode CNE4_3, the fifth connection electrode CNE5_3, and the eighth connection electrode CNE8_3, and the second connection electrode layer CNEL2_3 including the second connection electrode CNE2_3, the third connection electrode CNE3_3, the sixth connection electrode CNE6_3, and the seventh connection electrode CNE7_3.

The stacking relationship and disposition relationship of the first connection electrode layer CNEL1_3 and the second connection electrode layer CNEL2_3 are substantially the same as those of the first connection electrode layer CNEL1_1 and the second connection electrode layer CNEL2_1 of the display device 1_1 according to the embodiment of FIG. 22, and a detailed description thereof will be omitted.

The first connection electrode CNE1_3 may be disposed on the first alignment electrode RME1. The first connection electrode CNE1_3 may generally have the second width W2 in the first direction DR1, extend in the second direction DR2, and have a shape that is bent at least once in the first direction DR1 near the center of the emission area EMA.

A portion of the first connection electrode CNE1_3 extending in the second direction DR2 may be in contact with the second end of the first light emitting element ED1_1, and a portion thereof bent in the first direction DR1 may be electrically connected to the sixth connection electrode CNE6_3 through the first node contact portion CTN1_2. The portion of the first connection electrode CNE1_3 bent in the first direction DR1 may cross a separation space between the first light emitting element ED1_1 and the third light emitting element ED3_1 in the second direction DR2.

The first connection electrode CNE1_3 may partially overlap the first narrow passage EP1 in the emission area EMA to cover the central portion HL1 of the first narrow passage EP1 in a plan view. For example, in the first narrow passage EP1, the first connection electrode CNE1_3 may reach a point beyond the central portion HL1 of the first narrow passage EP1 to completely cover the central portion HL1 of the first narrow passage EP1. Accordingly, contact between the first connection electrode CNE1_3 and the second end of the first light emitting element ED1_1 may be secured although the first light emitting element ED1_1 is not properly aligned in the display device manufacturing process.

The second connection electrode CNE2_3 may be disposed on the other side of the second alignment electrode RME2 in the first direction DR1. The second connection electrode CNE2 may generally have the first width W1 in the first direction DR1 and may have a shape extending in the second direction DR2 to the vicinity of the center of the emission area EMA. The second connection electrode CNE2_3 may be in contact with the first end of the first light emitting element ED1_1.

Other description of the second connection electrode CNE2_3 will be omitted since it is substantially the same as the description of the second connection electrode CNE2_1 of FIG. 22.

The third connection electrode CNE3_3 may be disposed on one side of the second alignment electrode RME2 in the first direction DR1. The third connection electrode CNE3_3 may generally have the first width W1 in the first direction DR1, extend in the second direction DR2, and have a shape that is bent at least once in the first direction DR1 near the center of the emission area EMA.

A portion of the third connection electrode CNE3_3 extending in the second direction DR2 may be in contact with the first end of the second light emitting element ED2_1, and a portion thereof bent in the first direction DR1 may be electrically connected to the eighth connection electrode CNE8_3 through the second node contact portion CTN2_2. The portion of the third connection electrode CNE3_3 bent in the first direction DR1 may cross a separation space between the second light emitting element ED2 and the fourth light emitting element ED4 in the second direction DR2.

The fourth connection electrode CNE4_3 may be disposed on the third alignment electrode RME3. The fourth connection electrode CNE4_3 may generally have the second width W2 in the first direction DR1 and may have a shape extending in the second direction DR2 to the vicinity of the center of the emission area EMA. The fourth connection electrode CNE4_3 may be in contact with the second end of the second light emitting element ED2_1.

The fourth connection electrode CNE4_3 may partially overlap the second narrow passage EP2 in the emission area EMA to cover the central portion HL2 of the second narrow passage EP2 in a plan view. For example, in the second narrow passage EP2, the fourth connection electrode CNE4_3 may reach a point beyond the central portion HL2 of the second narrow passage EP2 to completely cover the central portion HL2 of the second narrow passage EP2. Accordingly, contact between the fourth connection electrode CNE4_3 and the second end of the second light emitting element ED2_1 may be secured although the second light emitting element ED2_1 is not properly aligned in the display device manufacturing process.

Other description of the fourth connection electrode CNE4_3 will be omitted since it is substantially the same as the description of the fourth connection electrode CNE4 of FIG. 22.

The fifth connection electrode CNE5_3 may be disposed on the first alignment electrode RME1 to be spaced apart from the first connection electrode CNE1_3 in the second direction DR2. The fifth connection electrode CNE5_3 may generally have the second width W2 in the first direction DR1, extend in the second direction DR2 from the vicinity of the center of the emission area EMA, and have a shape that is bent at least once in the first direction DR1 on the external bank BNL disposed on one side of the emission area EMA in the second direction DR2.

A portion of the fifth connection electrode CNE5_3 extending in the second direction DR2 may be in contact with the second end of the third light emitting element ED3_1, and a portion thereof bent in the first direction DR1 may be electrically connected to the seventh connection electrode CNE7_3 through the third node contact portion CTN3_2. A portion of the fifth connection electrode CNE5_3 bent in the first direction DR1 may be disposed outside the emission area EMA.

The fifth connection electrode CNE5_3 may partially overlap the first narrow passage EP1 in the emission area EMA to cover the central portion HL1 of the first narrow passage EP1 in a plan view. For example, in the first narrow passage EP1, the fifth connection electrode CNE5_3 may reach a point beyond the central portion HL1 of the first narrow passage EP1 to completely cover the central portion HL1 of the first narrow passage EP1. Accordingly, contact between the fifth connection electrode CNE5_3 and the second end of the third light emitting element ED3_1 may be secured although the third light emitting element ED3_1 is not properly aligned in the display device manufacturing process.

The sixth connection electrode CNE6_3 may be disposed on the other side of the second alignment electrode RME2 in the first direction DR1 to be spaced apart from the second connection electrode CNE2_3 in the second direction DR2. The sixth connection electrode CNE6_3 may generally have the first width W1 in the first direction DR1 and may have a shape extending in the second direction DR2 from the vicinity of the center of the emission area EMA. The sixth connection electrode CNE6_3 may be in contact with the first end of the third light emitting element ED3_1.

The seventh connection electrode CNE7_3 may be disposed on one side of the second alignment electrode RME2 in the first direction DR1 to be spaced apart from the third connection electrode CNE3_3 in the second direction DR2. The seventh connection electrode CNE7_3 may generally have the first width W1 in the first direction DR1 from the vicinity of the center of the emission area EMA, extend in the second direction DR2, and have a shape that is bent at least once in the first direction DR1 on the external bank BNL disposed on one side of the emission area EMA in the second direction DR2.

A portion of the seventh connection electrode CNE7_3 extending in the second direction DR2 may be in contact with the first end of the fourth light emitting element ED4_1 in the emission area EMA. A portion of the seventh connection electrode CNE7_3 bent in the first direction DR1 may be electrically connected to the fifth connection electrode CNE5_3 through the third node contact portion CTN3_2.

The eighth connection electrode CNE8_3 may be disposed on the third alignment electrode RME3 to be spaced apart from the fourth connection electrode CNE4_3 in the second direction DR2. The eighth connection electrode CNE8_3 may generally have the second width W2 in the first direction DR1, be bent in the first direction DR1 near the center of the emission area EMA, and have a shape extending in the second direction DR2 in the emission area EMA.

A portion of the eighth connection electrode CNE8_3 extending in the second direction DR2 may be in contact with the second end of the fourth light emitting element ED4_1, and a portion thereof bent in the first direction DR1 may be electrically connected to the third connection electrode CNE3_3 through the second node contact portion CTN2_2.

The eighth connection electrode CNE8_3 may partially overlap the second narrow passage EP2 in the emission area EMA to cover the central portion HL2 of the second narrow passage EP2 in a plan view. For example, in the second narrow passage EP2, the eighth connection electrode CNE8_3 may reach a point beyond the central portion HL2 of the second narrow passage EP2 to completely cover the central portion HL2 of the second narrow passage EP2. Accordingly, although the fourth light emitting element ED4_1 is not properly aligned in the display device manufacturing process, contact between the eighth connection electrode CNE8_3 and the second end of the fourth light emitting element ED4_1 may be secured.

According to the configuration as described above, in the display device 1_3 according to the embodiment, four different light emitting elements ED may be connected in series to improve the luminous efficiency of the pixel, and the contact of the second end of each of the light emitting elements ED may be stably secured.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments.

What is claimed is:

1. A display device comprising:
an external bank disposed on a substrate defining an emission area;
a first light emitting element and a second light emitting element spaced apart from each other, each disposed on the substrate in the emission area and including a first end having a first polarity and a second end having a second polarity;
a first connection electrode disposed on the substrate and electrically contacting the first end of the first light emitting element;
a second connection electrode disposed on the substrate, spaced apart from the first connection electrode, and electrically contacting the first end of the second light emitting element;
a first insulating layer disposed on the first connection electrode and the second connection electrode and exposing the second end of the first light emitting element and the second end of the second light emitting element;
a third connection electrode disposed on the first insulating layer and electrically contacting the second end of the first light emitting element; and
a fourth connection electrode disposed on the first insulating layer, spaced apart from the third connection electrode, electrically contacting the second end of the second light emitting element, and electrically connected to the first connection electrode through a first contact hole penetrating the first insulating layer.

2. The display device of claim 1, wherein
each of the first end of the first light emitting element and the first end of the second light emitting element comprises a p-type semiconductor,
each of the second end of the first light emitting element and the second end of the second light emitting element comprises an n-type semiconductor, and
the second end of the first light emitting element and the second end of the second light emitting element are disposed to face each other.

3. The display device of claim 2, wherein the first contact hole is not disposed in the emission area.

4. The display device of claim 3, wherein in the emission area,
the first connection electrode and the fourth connection electrode are spaced apart from each other,
the third connection electrode is disposed between the first connection electrode and the fourth connection electrode,
the second connection electrode and the third connection electrode are spaced apart from each other, and
the fourth connection electrode is disposed between the second connection electrode and the third connection electrode.

5. The display device of claim 4, wherein
a first power voltage is supplied to the second connection electrode,
a second power voltage is supplied to the third connection electrode, and
a potential value of the first power voltage is greater than a potential value of the second power voltage.

6. The display device of claim 4, further comprising:
a third light emitting element and a fourth light emitting element spaced apart from the first light emitting element and the second light emitting element, each disposed on the substrate in the emission area and including a first end having the first polarity and the second end having a second polarity;
a fifth connection electrode disposed between the substrate and the first insulating layer and electrically contacting the first end of the third light emitting element;
a sixth connection electrode disposed between the substrate and the first insulating layer, spaced apart from the fifth connection electrode, and electrically contacting the first end of the fourth light emitting element;
a seventh connection electrode disposed on the first insulating layer and electrically contacting the second end of the third light emitting element; and
an eighth connection electrode disposed on the first insulating layer, spaced apart from the seventh connection electrode, and electrically contacting the second end of the fourth light emitting element, wherein
the first connection electrode and the seventh connection electrode are electrically connected through a second contact hole penetrating the first insulating layer, and
the fourth connection electrode and the sixth connection electrode are electrically connected through a third contact hole penetrating the first insulating layer.

7. The display device of claim 6, wherein
each of the first end of the third light emitting element and the first end of the fourth light emitting element comprises a p-type semiconductor,
each of the second end of the third light emitting element and the second end of the fourth light emitting element comprises an n-type semiconductor,
the second end of the third light emitting element and the second end of the fourth light emitting element are disposed to face each other,
the second contact hole is disposed between the first light emitting element and the third light emitting element in the emission area, and
the third contact hole is disposed between the second light emitting element and the fourth light emitting element in the emission area.

8. The display device of claim 4, wherein the first insulating layer is not disposed between the third connection electrode and the fourth connection electrode.

9. The display device of claim 1, wherein
each of the first end of the first light emitting element and the first end of the second light emitting element comprises a p-type semiconductor,
each of the second end of the first light emitting element and the second end of the second light emitting element comprises an n-type semiconductor, and
the first end of the first light emitting element and the first end of the second light emitting element are disposed to face each other.

10. The display device of claim 9, wherein the first contact hole is not disposed in the emission area.

11. The display device of claim 10, wherein in the emission area,
the first connection electrode and the fourth connection electrode are spaced apart from each other,
the second connection electrode is disposed between the first connection electrode and the fourth connection electrode,
the second connection electrode and the third connection electrode are spaced apart from each other, and
the first connection electrode is disposed between the second connection electrode and the third connection electrode.

12. The display device of claim 11, wherein
a first power voltage is supplied to the second connection electrode,
a second power voltage is supplied to the third connection electrode, and
a potential value of the first power voltage is greater than a potential value of the second power voltage.

13. The display device of claim 11, further comprising:
a third light emitting element and a fourth light emitting element spaced apart from the first light emitting element and the second light emitting element, each disposed on the substrate in the emission area and including a first end having the first polarity and a second end having the second polarity;
a fifth connection electrode disposed between the substrate and the first insulating layer and electrically contacting the first end of the third light emitting element;
a sixth connection electrode disposed between the substrate and the first insulating layer, spaced apart from the fifth connection electrode, and electrically contacting the first end of the fourth light emitting element;
a seventh connection electrode disposed on the first insulating layer and electrically contacting the second end of the third light emitting element; and
an eighth connection electrode disposed on the first insulating layer, spaced apart from the seventh connection electrode, and electrically contacting the second end of the fourth light emitting element, wherein
the third connection electrode and the fifth connection electrode are electrically connected through a second contact hole penetrating the first insulating layer, and
the second connection electrode and the eighth connection electrode are electrically connected through a third contact hole penetrating the first insulating layer.

14. The display device of claim 13, wherein
each of the first end of the third light emitting element and the first end of the fourth light emitting element comprises a p-type semiconductor,
each of the second end of the third light emitting element and the second end of the fourth light emitting element comprises an n-type semiconductor,
the first end of the third light emitting element and the first end of the fourth light emitting element are disposed to face each other,
the second contact hole is disposed between the first light emitting element and the third light emitting element in the emission area, and
the third contact hole is disposed between the second light emitting element and the fourth light emitting element in the emission area.

15. The display device of claim 11, wherein the first insulating layer is not disposed between the third connection electrode and the external bank and between the fourth connection electrode and the external bank.

16. A display device comprising:
an external bank disposed on a substrate defining an emission area;
a first light emitting element and a second light emitting element spaced apart from each other, each disposed on the substrate in the emission area and including a first end having a first polarity and a second end having a second polarity;
a first connection electrode disposed on the substrate and electrically contacting the first end of the first light emitting element;
a second connection electrode disposed on the substrate, spaced apart from the first connection electrode, and electrically contacting the first end of the second light emitting element;
a first insulating layer disposed on the first connection electrode and the second connection electrode and exposing the second end of the first light emitting element and the second end of the second light emitting element;
a third connection electrode disposed on the first insulating layer, electrically contacting the second end of the first light emitting element, and having a width greater than a width of the first connection electrode in a direction; and
a fourth connection electrode disposed on the first insulating layer, spaced apart from the third connection electrode, electrically contacting the second end of the second light emitting element, and having a width greater than a width of the second connection electrode in the direction.

17. The display device of claim 16, wherein
each of the first end of the first light emitting element and the first end of the second light emitting element comprises a p-type semiconductor,
each of the second end of the first light emitting element and the second end of the second light emitting element comprises an n-type semiconductor, and
the second end of the first light emitting element and the second end of the second light emitting element are disposed to face each other.

18. The display device of claim 17, further comprising:
a first alignment electrode, a second alignment electrode, and a third alignment electrode sequentially arranged to be spaced apart from each other on the substrate in the emission area, wherein
the first light emitting element is disposed between the first alignment electrode and the second alignment electrode,
the second light emitting element is disposed between the second alignment electrode and the third alignment electrode,
the third connection electrode is disposed on the second alignment electrode and covers at least half of a distance between the first alignment electrode and the second alignment electrode, and
the fourth connection electrode is disposed on the second alignment electrode and covers at least half of a distance between the second alignment electrode and the third alignment electrode.

19. The display device of claim 16, wherein
each of the first end of the first light emitting element and the first end of the second light emitting element comprises a p-type semiconductor,
each of the second end of the first light emitting element and the second end of the second light emitting element comprises an n-type semiconductor, and
the first end of the first light emitting element and the first end of the second light emitting element are disposed to face each other.

20. The display device of claim 19, further comprising:
a first alignment electrode, a second alignment electrode, and a third alignment electrode sequentially arranged to be spaced apart from each other on the substrate in the emission area, wherein
the second light emitting element is disposed between the first alignment electrode and the second alignment electrode,
the first light emitting element is disposed between the second alignment electrode and the third alignment electrode,
the third connection electrode is disposed on the third alignment electrode and covers at least half of a distance between the second alignment electrode and the third alignment electrode, and
the fourth connection electrode is disposed on the first alignment electrode and covers at least half of a distance between the first alignment electrode and the second alignment electrode.
